(19) United States
(12) Patent Application Publication
(10) Pub. No.: US 2024/0324172 A1
(43) Pub. Date: Sep. 26, 2024

(54) METHOD OF MANUFACTURING SEMICONDUCTOR DEVICES

(71) Applicant: SAMSUNG ELECTRONICS CO., LTD., Suwon-si (KR)

(72) Inventors: Donghoon KWON, Suwon-si (KR); Yanghee Lee, Suwon-si (KR)

(73) Assignee: SAMSUNG ELECTRONICS CO., LTD., Suwon-si (KR)

(21) Appl. No.: 18/612,672

(22) Filed: Mar. 21, 2024

(30) Foreign Application Priority Data
Mar. 24, 2023 (KR) 10-2023-0039150
May 16, 2023 (KR) 10-2023-0063250

(51) Int. Cl. H10B 12/00

(52) U.S. Cl. CPC H10B 12/09; H10B 12/0335

(57) ABSTRACT

A method of manufacturing a semiconductor device includes preparing a substrate including a plurality of active regions and a peripheral active region defined by an isolation layer, forming a word line in a word line trench that crosses the plurality of active regions, forming a plurality of bit line structures, each of the plurality of bit line structures including a bit line on the plurality of active regions, forming a plurality of gate line structures, each of the plurality of gate line structures including a gate line on the peripheral active region, forming a plurality of buried contacts between the plurality of bit line structures, the plurality of buried contacts being connected to the plurality of active regions, and forming an inter-gate insulating layer between the plurality of gate line structures, the inter-gate insulating layer including an oxide having impurities.

### CROSS-REFERENCE TO RELATED APPLICATION

This application is based on and claims priority to Korean Patent Application No. 10-2023-0063250, filed on May 16, 2023, in the Korean Intellectual Property Office, and Korean Patent Application No. 10-2023-039150, filed on Mar. 24, 2023, the disclosures of which are incorporated by reference herein in their entireties.

### BACKGROUND

Example embodiments of the disclosure relate to a method of manufacturing a semiconductor device, and more particularly, to a method of manufacturing a semiconductor device including a contact plug.

According to the rapid development of the electronics industry and the needs of users, electronic devices have become smaller and lighter. Therefore, a high degree of integration may be required for semiconductor devices used in electronic devices. As the degree of integration of semiconductor devices increases, design rules for components of semiconductor devices decrease and aspect ratios increase, increasing the difficulty in securing connection reliability between components of semiconductor devices.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

Provided is a method of manufacturing a semiconductor device having a contact plug ensuring connection reliability.

Additional aspects will be set forth in part in the description which follows and, in part, will be apparent from the description, or may be learned by practice of the presented embodiments.

According to an aspect of an example embodiment, a method of manufacturing a semiconductor device may include preparing a substrate including a plurality of active regions and a peripheral active region defined by an isolation layer, forming a word line in a word line trench that crosses the plurality of active regions, forming a plurality of bit line structures, each of the plurality of bit line structures including a bit line on the plurality of active regions, forming a plurality of gate line structures, each of the plurality of gate line structures including a gate line on the peripheral active region, forming a plurality of buried contacts between the plurality of bit line structures, the plurality of buried contacts being connected to the plurality of active regions, forming an inter-gate insulating layer between the plurality of gate line structures, the inter-gate insulating layer including an oxide having impurities, forming a gate cover insulating layer at least partially covering the plurality of gate line structures and the inter-gate insulating layer, forming a peripheral contact plug connected to the peripheral active region through the gate cover insulating layer and the inter-gate insulating layer, forming a plurality of landing pads on the plurality of buried contacts, forming a peripheral bit line on the peripheral contact plug, and forming a plurality of capacitor structures on the plurality of landing pads.

According to an aspect of an example embodiment, a method of manufacturing a semiconductor device may include forming, on a substrate, a plurality of gate line structures, each of the plurality of gate line structures including a gate line, forming a preliminary inter-gate insulating layer at least partially filling spaces between the plurality of gate line structures and at least partially covering top surfaces of the plurality of gate line structures, the preliminary inter-gate insulating layer including an oxide having first impurities, forming an inter-gate insulating layer including an oxide having second impurities by removing an upper portion of the preliminary inter-gate insulating layer such that the plurality of gate line structures are exposed, forming a gate cover insulating layer at least partially covering the plurality of gate line structures and the inter-gate insulating layer, forming a peripheral contact hole through the gate cover insulating layer and the inter-gate insulating layer, the substrate being exposed at a bottom of the peripheral contact hole, and forming a peripheral contact plug at least partially filling the peripheral contact hole.

According to an aspect of an example embodiment, a method of manufacturing a semiconductor device may include preparing a substrate in which a plurality of active regions and a peripheral active region are defined by an isolation layer, forming a word line trench by removing portions of the isolation layer and portions of each of the plurality of active regions, the word line trench crossing the plurality of active regions in the substrate and extending in a first horizontal direction, forming a word line in the word line trench, forming a plurality of bit line structures extending parallel to each other in a second horizontal direction orthogonal to the first horizontal direction on the plurality of active regions, forming a plurality of gate line structures, each of the plurality of gate line structures including a gate line on the peripheral active region, forming a plurality of buried contacts between the plurality of bit line structures, the plurality of buried contacts being connected to the plurality of active regions, forming a preliminary inter-gate insulating layer at least partially filling spaces between the plurality of gate line structures and at least partially covering top surfaces of the plurality of gate line structures, the preliminary inter-gate insulating layer including an oxide having first impurities including nitrogen, forming an inter-gate insulating layer by removing an upper portion of the preliminary inter-gate insulating layer such that the plurality of gate line structures are exposed, the inter-gate insulating layer including an oxide having second impurities including nitrogen, forming a gate cover insulating layer at least partially covering the plurality of gate line structures and the inter-gate insulating layer, forming a first peripheral contact hole through the gate cover insulating layer and the inter-gate insulating layer, the peripheral active region being exposed at a bottom of the first peripheral contact hole, forming a second peripheral contact hole through the gate cover insulating layer, wherein at least one gate line of the plurality of gate line structures is exposed at a bottom of the second peripheral contact hole, forming a preliminary contact material layer at least partially filling the first peripheral contact hole and the second peripheral contact hole and at least partially covering a top surface of the gate cover insulating layer, forming a first peripheral contact plug and a second peripheral contact plug at least partially filling the first peripheral contact hole and the second peripheral contact hole, respectively, by removing an upper portion of the preliminary contact material layer, forming a plurality of landing pads on the plurality of buried contacts, forming a peripheral bit line on each of the first peripheral contact plug and the second peripheral contact plug, and forming a plurality of capacitor structures on the plurality of landing pads, where the first peripheral contact plug has a substantially constant horizontal width and extends in a vertical direction.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a block diagram illustrating a semiconductor device according to embodiments;

FIG. 2 is a layout diagram illustrating main components of a semiconductor device according to embodiments;

FIGS. 3A to 3E, 4A to 4E, 5A to 5E, 6A to 6D, 7 to 12, 13A to 13E, and 14A to 14E are cross-sectional views illustrating a method of manufacturing a semiconductor device, according to embodiments;

FIGS. 15A to 15E are cross-sectional views illustrating a semiconductor device according to embodiments;

FIGS. 16 and 17 are cross-sectional views illustrating a method of manufacturing a semiconductor device, according to embodiments;

FIG. 18 is a cross-sectional view illustrating a semiconductor device according to embodiments;

FIGS. 19 and 20 are cross-sectional views illustrating a method of manufacturing a semiconductor device, according to embodiments;

FIG. 21 is a cross-sectional view illustrating a semiconductor device according to embodiments;

FIGS. 22 and 23 are cross-sectional views illustrating a method of manufacturing a semiconductor device, according to embodiments;

FIG. 24 is a cross-sectional view illustrating a semiconductor device according to embodiments;

FIGS. 25 and 26 are cross-sectional views illustrating a method of manufacturing a semiconductor device, according to embodiments;

FIG. 27 is a cross-sectional view illustrating a semiconductor device according to embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

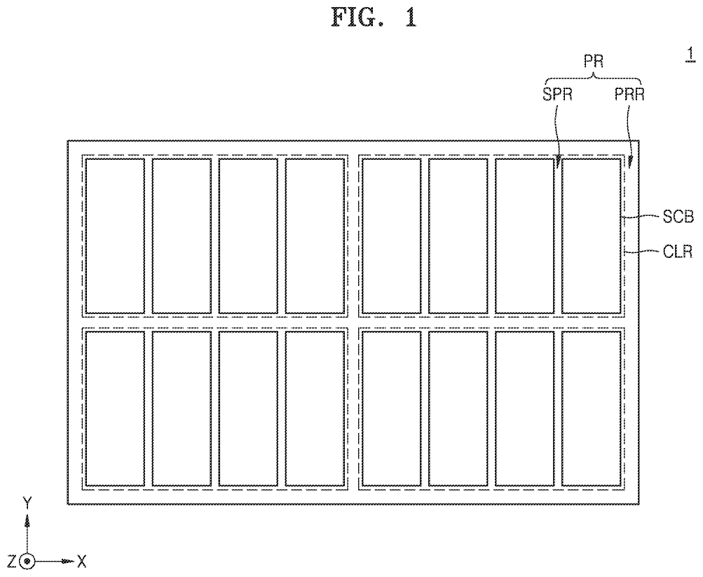

FIG. 1 is a block diagram illustrating a semiconductor device 1 according to embodiments.

Referring to FIG. 1, the semiconductor device 1 may include a cell region

CLR in which memory cells are disposed and a main peripheral region PRR surrounding or at least partially surrounding the cell region CLR.

According to an embodiment, the cell region CLR may include sub peripheral regions SPR between cell blocks SCB such that the cell blocks SCB are divided by the sub peripheral regions SPR. A plurality of memory cells may be disposed in the cell blocks SCB. As described herein, a cell block SCB may refer to an area in which the memory cells are regularly arranged at regular intervals, and the cell block SCB may be referred to as a sub-cell block.

Logic cells for inputting/outputting of electrical signals to/from the memory cells may be disposed in the main peripheral region PRR and the sub peripheral region SPR. In some embodiments, the main peripheral region PRR may be referred to as a peripheral circuit region and the sub peripheral region SPR may be referred to as a core circuit region. A peripheral region PR may include the main peripheral region PRR and the sub peripheral region SPR. That is, the peripheral region PR may be a core and peripheral circuit region including a peripheral circuit region and a core circuit region. In some embodiments, at least a portion of the sub periphery region SPR may be provided only as a space for dividing cell blocks SCB from each other.

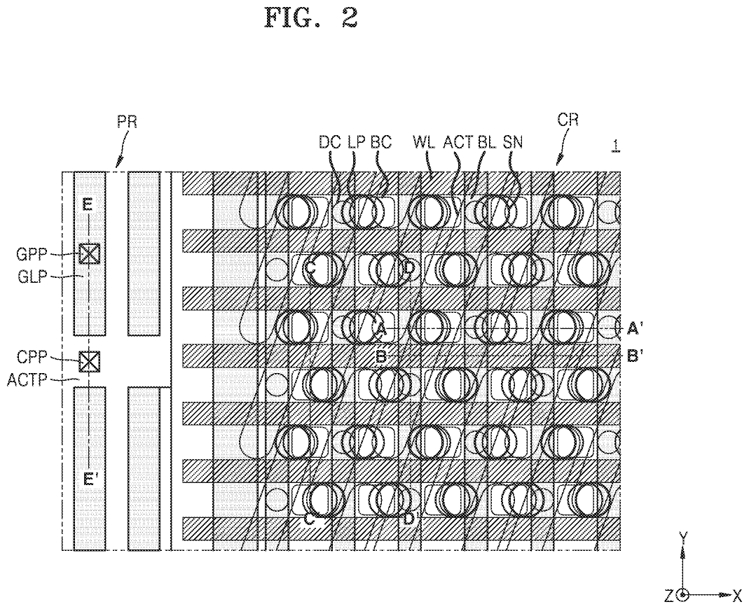

FIG. 2 is a layout diagram illustrating main components of a semiconductor device 1 according to embodiments.

Referring to FIG. 2, the semiconductor device 1 may include a memory cell region CR and a peripheral region PR. The semiconductor device 1 may include a plurality of active regions ACT formed in the memory cell region CR and a peripheral active region ACTP formed in the peripheral region PR. The memory cell region CR may be the cell block SCB shown in FIG. 1, in which a plurality of memory cells are disposed, and the peripheral region PR may be the peripheral region PR, which includes the main peripheral region PRR and the sub peripheral region SPR shown in FIG. 1.

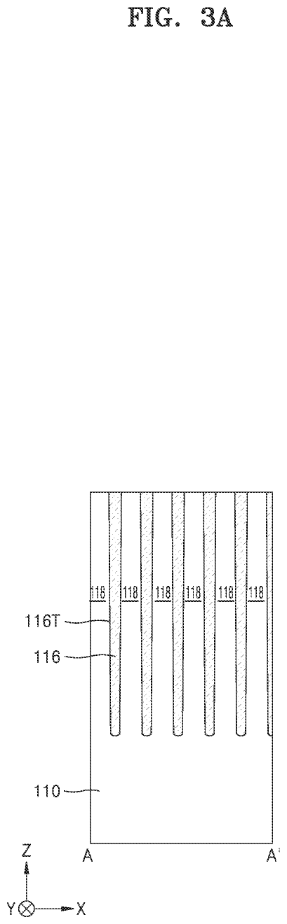

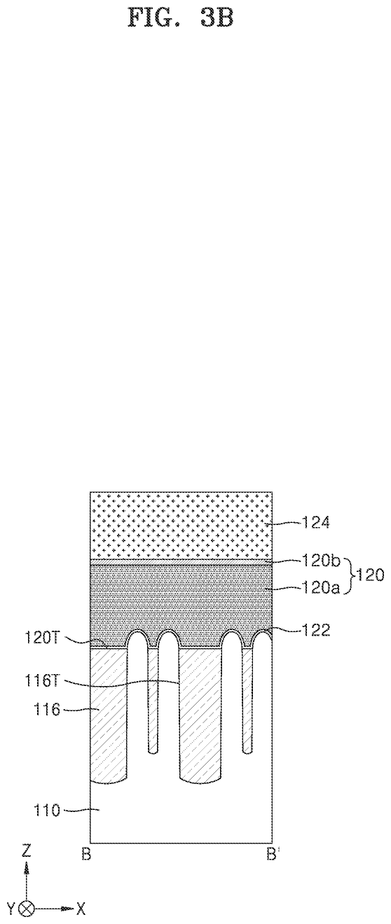

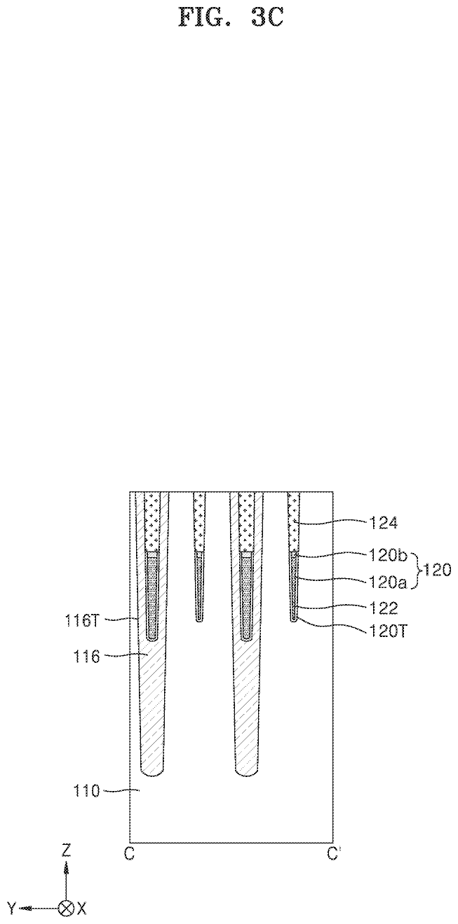

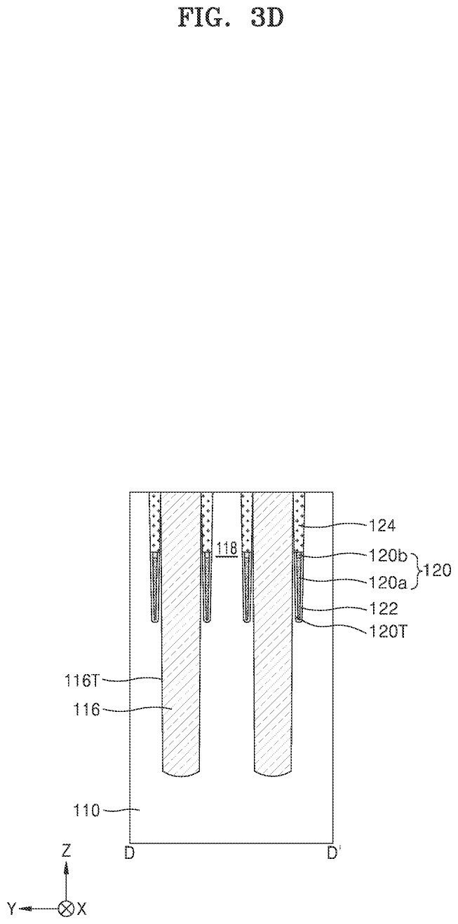

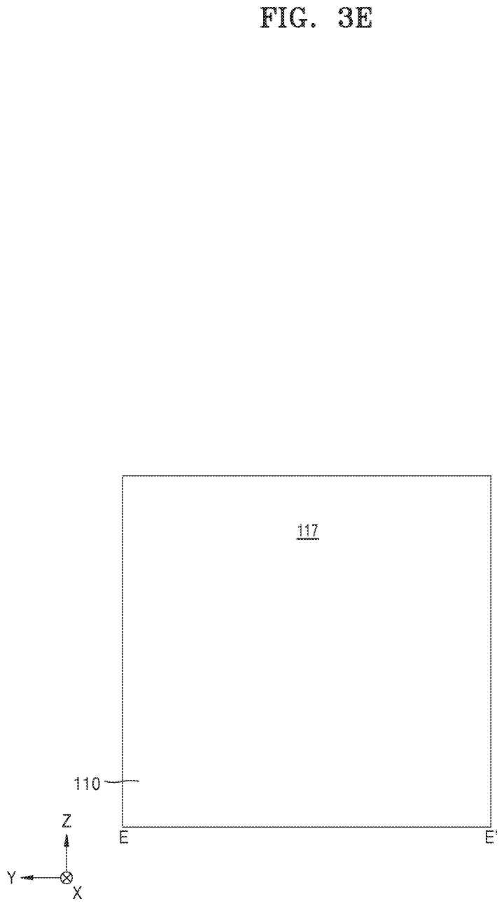

In some embodiments, the plurality of active regions ACT disposed in the memory cell region CR may be disposed to have long axes in an oblique direction with respect to a first horizontal direction (X direction) and a second horizontal direction (Y direction). The plurality of active regions ACT may be defined in a substrate 110 (see FIGS. 3A to 3D) by an isolation layer 116 (see FIGS. 3A to 3D).

A plurality of word lines WL may extend parallel to each other in the first horizontal direction (X direction) across the plurality of active regions ACT in the memory cell region CR. A plurality of bit lines BL may extend parallel to each other in the second horizontal direction (Y direction) crossing the first horizontal direction (X direction) on the plurality of word lines WL. The plurality of bit lines BL may be electrically connected to the plurality of active regions ACT through direct contacts DC.

In some embodiments, a plurality of buried contacts BC may be formed between two adjacent bit lines BL among the plurality of bit lines BL. In some embodiments, the plurality of buried contacts BC may be arranged in a line in each of the first horizontal direction (X direction) and the second horizontal direction (Y direction).

A plurality of landing pads LP may be formed on the plurality of buried contacts BC. The plurality of landing pads LP may be arranged to at least partially overlap the plurality of buried contacts BC. In some embodiments, each of the plurality of landing pads LP may extend to an upper portion of any one bit line BL among two adjacent bit lines BL.

A plurality of storage nodes SN may be formed on the plurality of landing pads LP. The plurality of storage nodes SN may be formed on top of a plurality of bit lines BL. The plurality of storage nodes SN may be lower electrodes of a plurality of capacitors, respectively. Each storage node SN may be electrically connected to the active region ACT through the landing pad LP and the buried contact BC.

In FIG. 2, components other than the peripheral active region ACTP and a plurality of gate line patterns GLP in the peripheral region PR are omitted for convenience of illustration.

The plurality of gate line patterns GLP may be disposed on the peripheral active region ACTP in the peripheral region PR. Although FIG. 2 illustrates that the plurality of gate line patterns GLP are disposed only on the plurality of peripheral active regions ACTP, the disclosure is not limited thereto. For example, the isolation layer 116 (see FIGS. 3A to 3D) defining the plurality of active regions ACT in the substrate 110 in the memory cell region CR may also be disposed in the peripheral region PR. In addition, the peripheral active region ACTP may be defined in the substrate 110 (see FIG. 3E) by a portion of the isolation layer 116 (see FIGS. 3A to 3D) disposed in the peripheral region PR. In addition, at least some of the plurality of gate line patterns GLP may extend outside the peripheral active region ACTP, that is, on a portion of the isolation layer 116 (see FIGS. 3A to 3D) disposed in the peripheral region PR.

Although FIG. 2 illustrates that the plurality of gate line patterns GLP extend parallel to each other in the second horizontal direction (Y direction) on the peripheral active region ACTP and have a substantially constant width in the first horizontal direction (X direction), the disclosure is not limited thereto. For example, each of the plurality of gate line patterns GLP may have various widths or vary in width, may have curves, or may extend in various directions.

The plurality of gate line patterns GLP may be formed at the same level as the plurality of bit lines BL. In some embodiments, the plurality of gate line patterns GLP and the plurality of bit lines BL may include the same material, or at least a portion of the gate line pattern GLP and at least a portion of the bit line BL may include the same material. For example, at least a portion of the gate line pattern GLP and at least a portion of the bit line BL may be formed by the same process.

A first peripheral contact plug CPP may be connected to the peripheral active region ACTP, and a second peripheral contact plug GPP may be connected to the gate line pattern GLP.

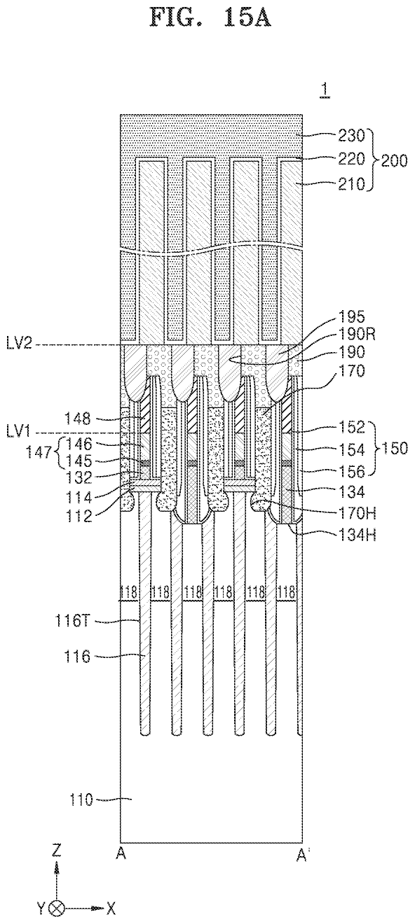

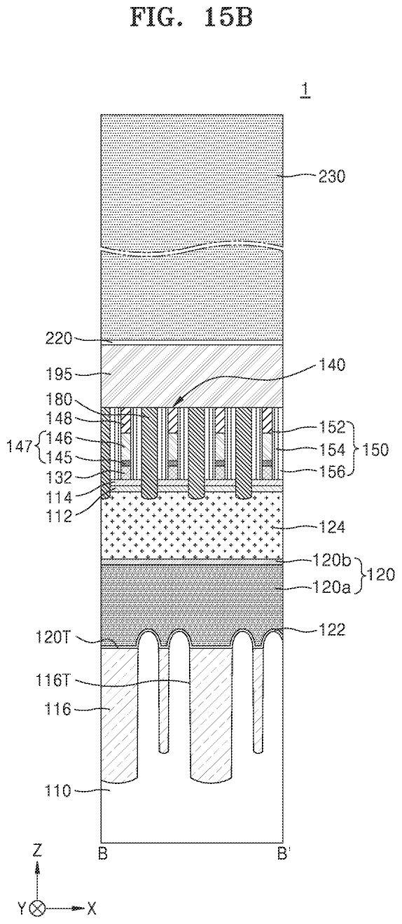

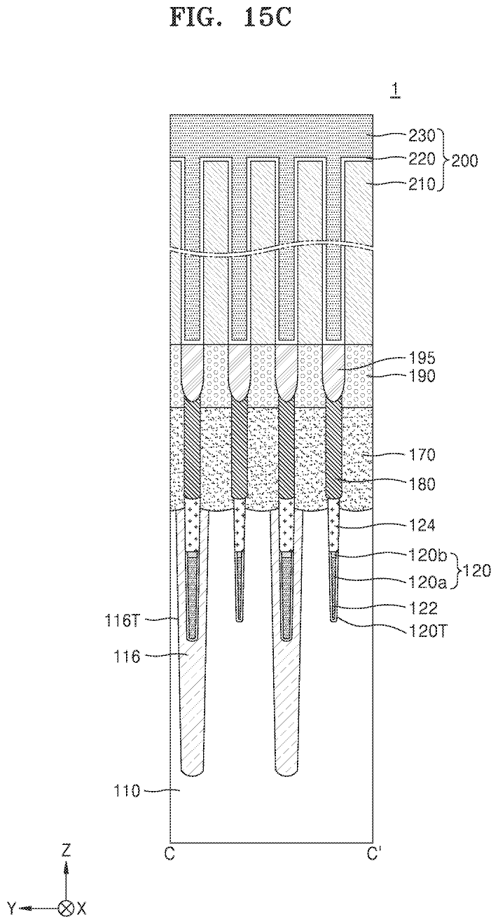

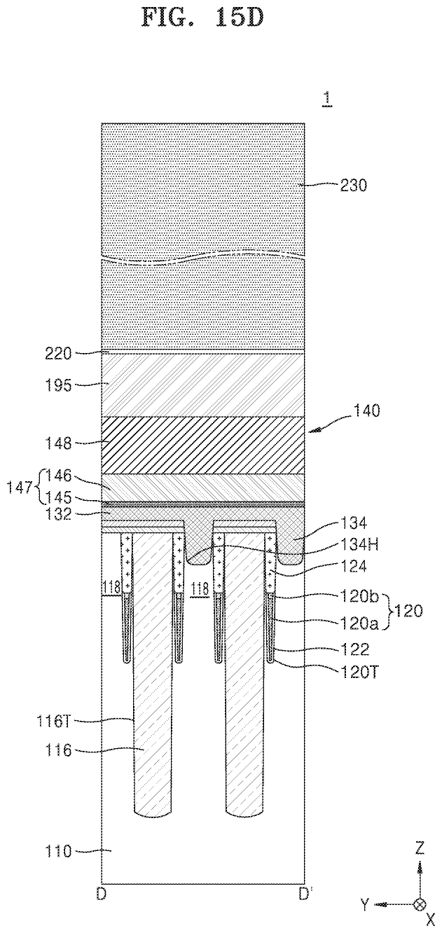

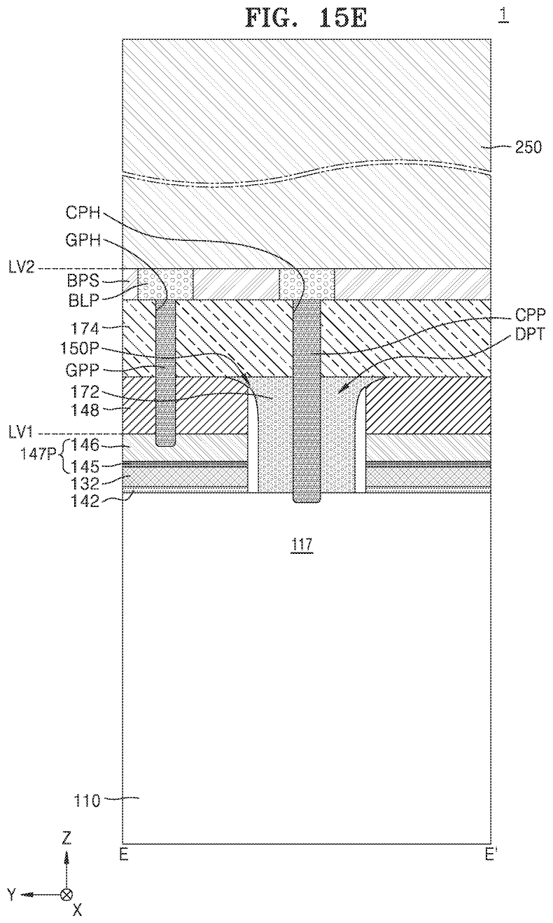

FIGS. 3A to 3E, 4A to 4E, 5A to 5E, 6A to 6D, 7 to 12, 13A to 13E, and 14A to 14E are cross-sectional views illustrating a method of manufacturing a semiconductor device, according to embodiments. FIGS. 15A to 15E are cross-sectional views illustrating a semiconductor device according to embodiments.

Specifically, FIGS. 3A, 4A, 5A, 6A, 13A, 14A, and 15A are cross-sectional views taken along line A-A′ in FIG. 2, FIGS. 3B, 4B, 5B, 6B, 13B, 14B, and 15B are cross-sectional views taken along line B-B′ in FIG. 2, and FIGS. 3C, 4C, 5C, 6C, 13C, 14C, and 15C are cross-sectional views taken along line C-C′ in FIG. 2. FIGS. 3D, 4D, 5D, 6D, 13D, 14D, and 15D are cross-sectional views taken along line D-D′ in FIG. 2, and FIGS. 3E, 4E, 5E, 7, 8, 9, 10, 11, 12, 13E, 14E, and 15E are cross-sectional views taken along line E-E′ in FIG. 2.

Referring to FIGS. 3A to 3E, isolation trenches 116T may be formed in a substrate 110, and isolation layers 116 filling or at least partially filling the isolation trenches 116T may be formed. In some embodiments, the isolation trenches 116T may be formed through an extreme ultraviolet (EUV) lithography process.

The substrate 110 may include, for example, silicon (Si), crystalline Si, polycrystalline Si, or amorphous Si. In some other embodiments, the substrate 110 may include a semiconductor element, such as germanium (Ge), or at least one compound semiconductor among silicon germanium (SiGe), silicon carbide (SiC), gallium arsenide (GaAs), indium arsenide (InAs), and indium phosphide (InP). In some embodiments, the substrate 110 may have a silicon on insulator (SOI) structure. For example, the substrate 110 may include a buried oxide (BOX) layer. The substrate 110 may include a conductive region (e.g., a well doped with impurities or a structure doped with impurities).

The isolation layer 116 may include, for example, a material including at least one of silicon oxide, silicon nitride, and silicon oxynitride. The isolation layer 116 may include a single layer made of one type of insulating film, a double layer made of two types of insulating film, or a multi-layer made of a combination of at least three types of insulating film. For example, the isolation layer 116 may include a double layer or a multi-layer made of an oxide film and a nitride film. However, the configuration of the isolation layer 116 is not limited to the above.

A plurality of active regions 118 may be defined by the isolation trench 116T and the isolation layer 116 in the substrate 110 in the memory cell region CR of FIG. 2. In addition, the isolation trench 116T and the isolation layer 116 may be formed in the peripheral region PR of FIG. 2, and thus, the peripheral active region 117 may be defined in the peripheral region PR. The active region 118 may be the active region ACT shown in FIG. 2, and the peripheral active region 117 may be the peripheral active region ACTP shown in FIG. 2. Similar to the active region ACT illustrated in FIG. 2, the active region 118 may have a relatively long shape that has a minor axis and a major axis in a plan view and extends in a direction of the major axis. The plurality of active regions 118 may be arranged in a row in an oblique direction with respect to the first horizontal direction (X direction) and the second horizontal direction (Y direction), and may be arranged in a row in the second horizontal direction (Y direction). The peripheral active region 117 may have a rectangular shape in a plan view but is not limited thereto and may have various planar shapes.

Thereafter, a portion of the active region 118 and a portion of the isolation layer 116 may be removed from the memory cell region CR to form a plurality of word line trenches 120T in the substrate 110. The plurality of word line trenches 120T may extend parallel to each other in the first horizontal direction (X direction) and may be arranged to cross the active region 118 and have substantially equal intervals in the second horizontal direction (Y direction), thereby having a line shape. In some embodiments, steps may be formed on bottom surfaces of the plurality of word line trenches 120T.

A plurality of gate dielectric layers 122, a plurality of word lines 120, and a plurality of buried insulating layers 124 may be sequentially formed inside the plurality of word line trenches 120T. The plurality of word lines 120 may constitute the plurality of word lines WL illustrated in FIG. 2. The plurality of word lines 120 may extend in parallel in the first horizontal direction (X direction), and may be arranged to cross the active region 118 and have substantially equal intervals in the second horizontal direction (Y direction), thereby having a line shape. The top surface of each of the plurality of word lines 120 may be at a level lower than that of the top surface of the substrate 110. The bottom surfaces of the plurality of word lines 120 may have concavo-convex shapes, and saddle fin structure transistors (saddle fin field-effect transistors (FETs) (FinFETs)) may be formed in the plurality of active regions 118.

As referred to herein, a level or a vertical level may indicate a height in a vertical direction (Z direction) with respect to the main surface or top surface of the substrate 110. That is, being at the same level or a certain level may refer to a position having the same or constant height in the vertical direction (Z direction) with respect to the main surface or top surface of the substrate 110, and being at a low/high level may refer to a position having a low/high height in the vertical direction (Z direction) with respect to the main surface of the substrate 110.

Each of the plurality of word lines 120 may have a stacked structure in which a lower word line layer 120a and an upper word line layer 120b are stacked. For example, the lower word line layer 120a may include a metal material, a conductive metal nitride, or a combination thereof. In some embodiments, the lower word line layer 120a may include Ti, TiN, Ta, TaN, W, WN, TiSiN, WSiN, or a combination thereof. For example, the upper word line layer 120b may include doped polysilicon. In some embodiments, the lower word line layer 120a may include a core layer and a barrier layer disposed between the core layer and the gate dielectric layer 122.

In some embodiments, before or after forming the plurality of word lines 120, impurity ions may be implanted into portions of the active region 118 of the substrate 110 on both sides of the plurality of word lines 120 to form a source region and a drain region in the plurality of active regions 118.

The gate dielectric layer 122 may include at least one of silicon oxide, silicon nitride, silicon oxynitride, oxide/nitride/oxide (ONO), and high-k dielectrics having a higher dielectric constant than silicon oxide. For example, the gate dielectric layer 122 may have a dielectric constant of about 10 to about 25.

The top surfaces of the plurality of buried insulating layers 124 may be at substantially the same level as the top surface of the substrate 110. The buried insulating layer 124 may include at least one material among silicon oxide, silicon nitride, silicon oxynitride, and a combination thereof.

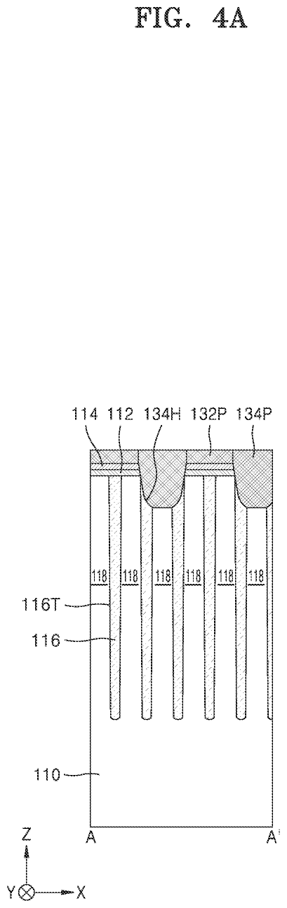

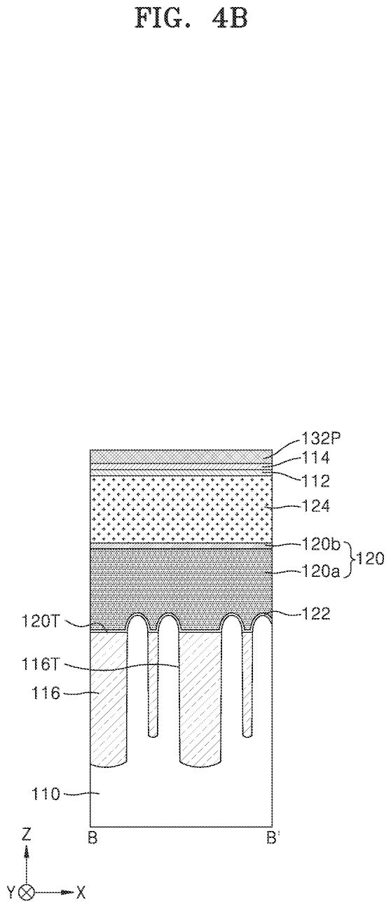

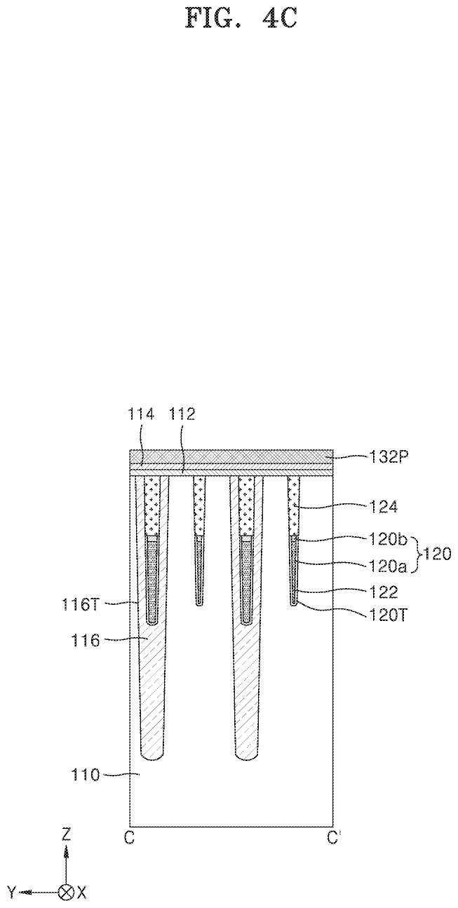

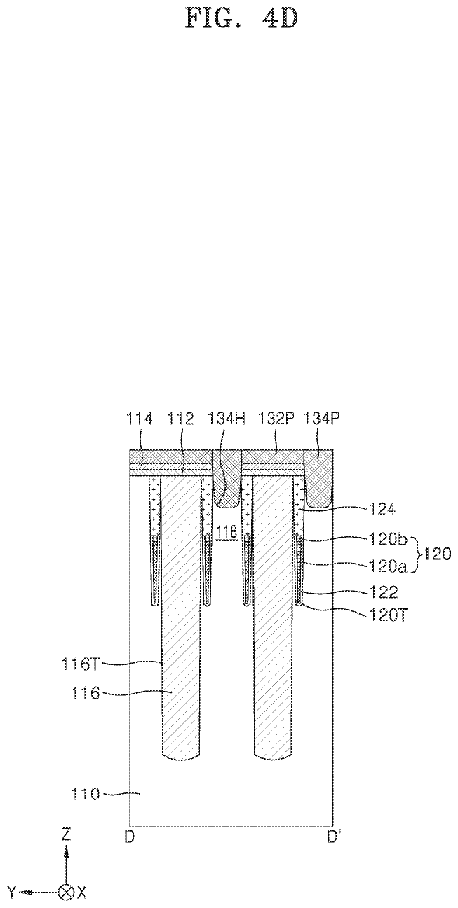

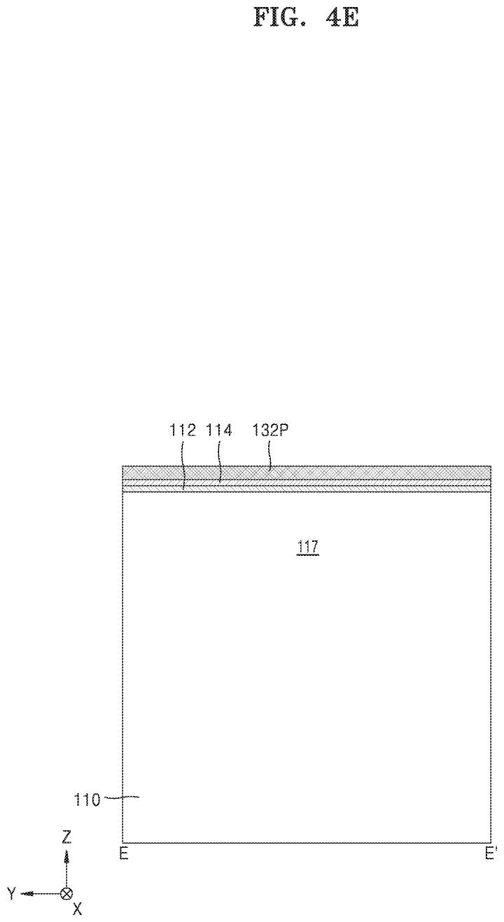

Referring to FIGS. 4A to 4E, a first insulating layer pattern 112 and a second insulating layer pattern 114 may be formed to sequentially cover or at least partially cover the substrate 110 in which the isolation layer 116, the plurality of active regions 118, the plurality of buried insulating layers 124, and the plurality of peripheral active regions 117 are formed. For example, a stacked structure in which the first insulating layer pattern 112 and the second insulating layer pattern 114 are stacked may include silicon oxide, silicon nitride, silicon oxynitride, a metal-based dielectric, or a combination thereof. In some embodiments, the first insulating layer pattern 112 may include silicon oxide and the second insulating layer pattern 114 may include silicon oxynitride. In some other embodiments, the first insulating layer pattern 112 may include a non-metal-based dielectric and the second insulating layer pattern 114 may include a metal-based dielectric. The first insulating layer pattern 112 and the second insulating layer pattern 114 may be collectively referred to as an insulating layer pattern.

Thereafter, a conductive semiconductor layer 132P may be formed on the stacked structure in which the first insulating layer pattern 112 and the second insulating layer pattern 114 are stacked. Then, a direct contact hole 134H exposing a source region in the active region 118 may be formed through the conductive semiconductor layer 132P, the second insulating layer pattern 114, and the first insulating layer pattern 112 and a direct contact conductive layer 134P filling or at least partially filling the direct contact hole 134H may be formed. In some embodiments, the direct contact hole 134H may extend into the active region 118 (i.e., into the source region). The conductive semiconductor layer 132P may include, for example, doped polysilicon. In some embodiments, the direct contact conductive layer 134P may include doped polysilicon. For example, the direct contact conductive layer 134P may include an epitaxial silicon layer. In some other embodiments, the direct contact conductive layer 134P may include metal or a metal compound that is a conductive material. For example, the direct contact conductive layer 134P may include metal, such as Ti or W, or a conductive material that is a compound of metal, such as Ti or W, and non-metal, such as Si, C, B, or N. In some embodiments, the direct contact conductive layer 134P may include TiN, WC, or WSi.

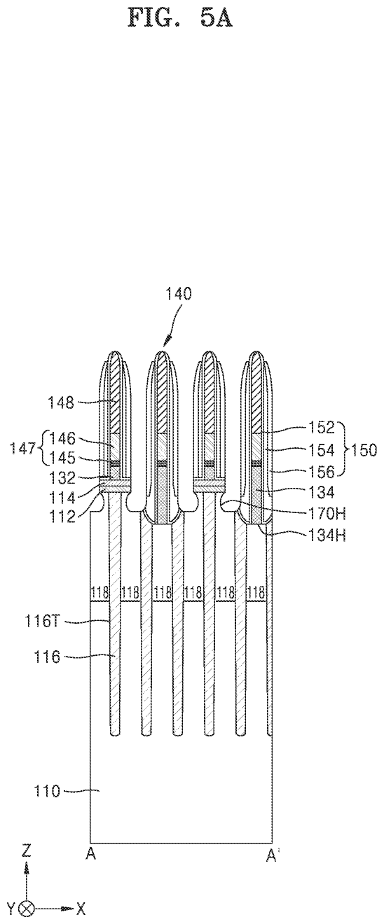

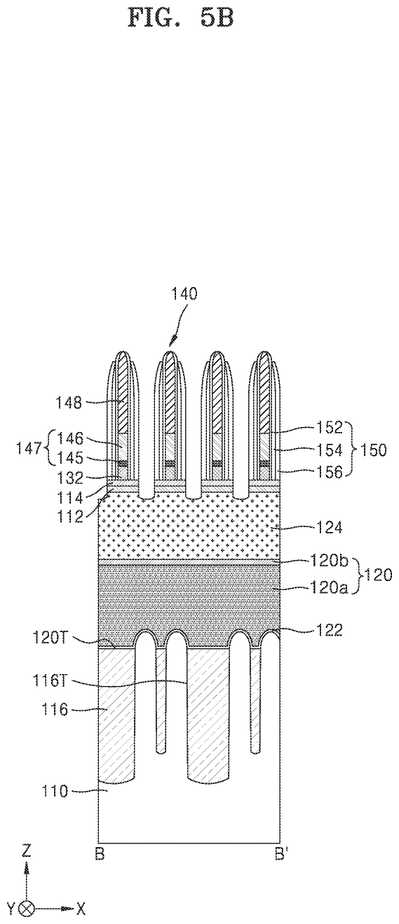

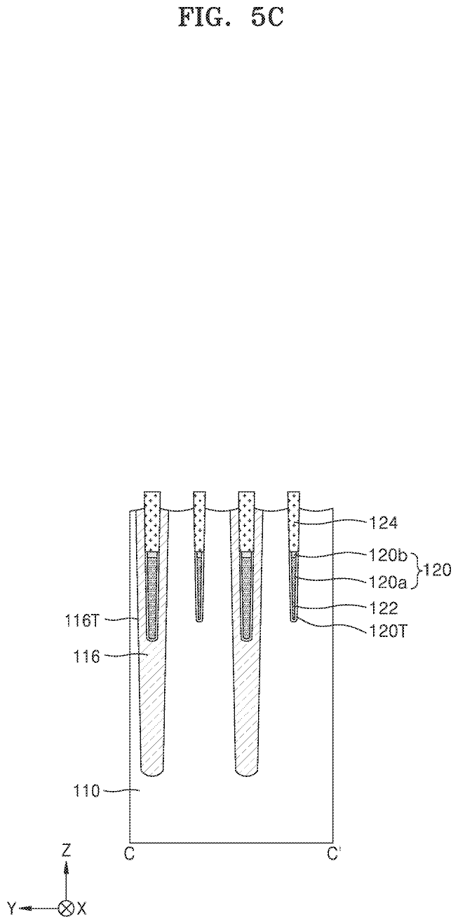

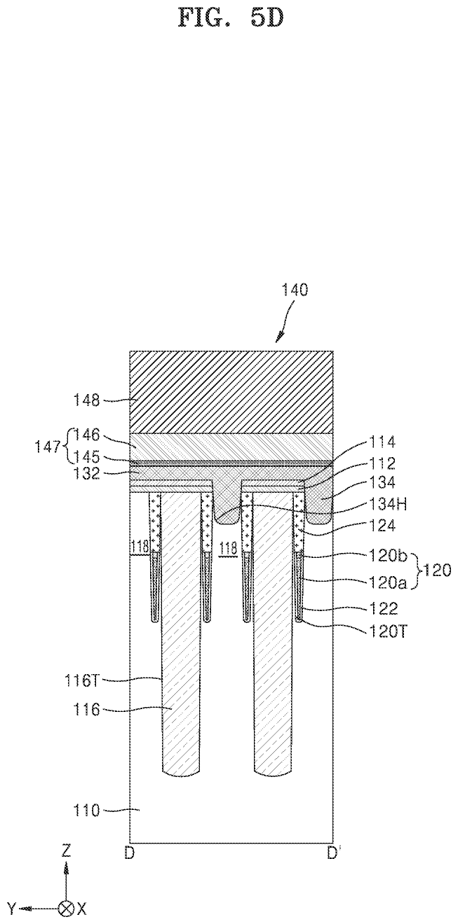

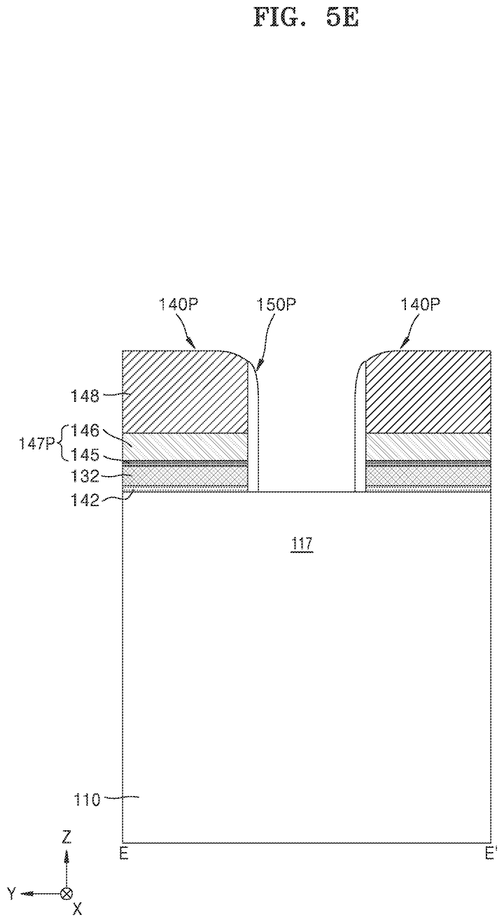

Referring to FIGS. 4A to 4E and FIGS. 5A to 5E, a metal-based conductive layer and an insulating capping layer covering or at least partially covering the conductive semiconductor layer 132P and the direct contact conductive layer 134P may be sequentially formed. In some embodiments, the metal-based conductive layer may have a stacked structure in which a first metal-based conductive layer and a second metal-based conductive layer are stacked. The first metal-based conductive layer, the second metal-based conductive layer, and the insulating capping layer may be etched to form a plurality bit lines 147 and a plurality of insulating capping lines 148. Each of the plurality of bit lines 147 may have a stacked structure in which a first metal-based conductive pattern 145 and a second metal-based conductive pattern 146, which have line shapes, are stacked.

In some embodiments, the first metal-based conductive pattern 145 may include titanium nitride (TiN) or Ti—Si—N(TSN) and the second metal-based conductive pattern 146 may include tungsten (W) or tungsten silicide (WSix). In some embodiments, the first metal-based conductive pattern 145 may function as a diffusion barrier. In some embodiments, the plurality of insulating capping lines 148 may include silicon nitride.

One bit line 147 and one insulating capping line 148 covering or at least partially covering the one bit line 147 may constitute one bit line structure 140. A plurality of bit line structures 140 each including the bit line 147 and the insulating capping line 148 covering or at least partially covering the bit line 147 may extend parallel to each other in the second horizontal direction (Y direction) parallel to the main surface of the substrate 110. The plurality of bit lines 147 may constitute the plurality of bit lines BL illustrated in FIG. 2.

A plurality of conductive semiconductor patterns 132 and a plurality of direct contact conductive patterns 134 may be formed through an etching process using the plurality of bit line structures 140 as an etch mask. For example, in the process of forming the plurality of bit line structures 140 including the plurality of bit lines 147 and the plurality of insulating capping lines 148 covering (or at least partially covering) the plurality of bit lines 147, an etching process may be additionally performed to remove a portion of the conductive semiconductor layer 132P and a portion of the direct contact conductive layer 134P that do not overlap the bit line structure 140 in the vertical direction (Z direction). Thus, a plurality of conductive semiconductor patterns 132 and a plurality of direct contact conductive patterns may be formed, which are a portion of the conductive semiconductor layer 132P and a portion of the direct contact conductive layer 134P that overlap the bit line structure 140 in the vertical direction (Z direction). In the etching process of forming the plurality of conductive semiconductor patterns 132 and the plurality of direct contact conductive patterns 134, the first insulating layer pattern 112 may function as an etching mask that protects the isolation layer 116 and the plurality of active regions 118 located under the first insulating layer pattern 112 from being removed. The first insulating layer pattern 112 may remain without being removed after the formation of the plurality of conductive semiconductor patterns 132 and the plurality of direct contact conductive patterns 134. In some embodiments, in the process of forming the plurality of conductive semiconductor patterns 132 and the plurality of direct contact conductive patterns 134, a portion of the second insulating layer pattern 114, which the plurality of bit lines 147 do not overlap, may be removed.

The plurality of direct contact conductive patterns 134 may constitute the plurality of direct contacts DC illustrated in FIG. 2. The plurality of bit lines 147 may be electrically connected to the plurality of active regions 118 through the plurality of direct contact conductive patterns 134. For example, each of the plurality of direct contact conductive patterns 134 may be formed to be connected to a middle portion of each of the plurality of active regions 118.

In some embodiments, the bit line structure 140 may further include a conductive semiconductor pattern 132 that is a portion of the conductive semiconductor layer 132P disposed between the second insulating layer pattern 114 and the first metal-based conductive pattern 145.

The conductive semiconductor pattern 132 may include, for example, doped polysilicon. The direct contact conductive pattern 134 may include doped polysilicon, metal, or a metal compound that is a conductive material.

An insulating spacer structure 150 may be formed to cover or at least partially cover both sidewalls of each of the plurality of bit line structures 140. Each of the plurality of insulating spacer structures 150 may include a first insulating spacer 152, a second insulating spacer 154, and a third insulating spacer 156. The second insulating spacer 154 may include a material having a lower dielectric constant than the first insulating spacer 152 and the third insulating spacer 156. In some embodiments, the first insulating spacer 152 and the third insulating spacer 156 may include nitride, and the second insulating spacer 154 may include oxide. In some embodiments, the first insulating spacer 152 and the third insulating spacer 156 may include nitride, and the second insulating spacer 154 may include a material having an etch selectivity with respect to the first insulating spacer 152 and the third insulating spacer 156. For example, when the first insulating spacer 152 and the third insulating spacer 156 include nitride, the second insulating spacer 154 may include oxide but may be removed in a subsequent process to be an air spacer.

A plurality of buried contact holes 170H may be formed between the plurality of bit line structures 140. An inner space of each of the buried contact holes 170H may defined by the insulating spacer structure 150 covering or at least partially covering respective sidewalls of two adjacent bit lines 147 between two adjacent bit lines 147 among a plurality of bit lines 147, and the active region 118.

The plurality of buried contact holes 170H may be formed by partially removing the second insulating layer pattern 114, the first insulating layer pattern 112, and the active region 118 using the insulating spacer structures 150, that cover (or at least partially cover) both sidewalls the plurality of insulating capping lines 148 and both sidewalls of the plurality of bit line structures 140, as an etch mask. In some embodiments, the plurality of buried contact holes 170H may be formed such that a space defined by the active region 118 is expanded by first performing an anisotropic etching process and then performing an isotropic etching process. The anisotropic etching process may be performed to remove portions of the second insulating layer pattern 114, the first insulating layer pattern 112, and the active region 118 using, as an etch mask, the plurality of insulating capping lines 148 and the insulating spacer structure 150 that covers (or at least partially covers) both sidewalls of the plurality of bit line structures 140. The isotropic etching process may be performed to further remove another portion of active region 118.

A plurality of gate line structures 140P and a plurality of gate insulating spacers 150P may be formed on the peripheral active region 117. Each of the gate line structures 140P may include a gate line 147P and an insulating capping line 148 covering or at least partially covering the gate line 147P. Each of the gate insulating spacers 150P may be formed to cover or at least partially cover sidewalls of the gate line structure 140P. The gate line 147P included in the gate line structure 140P may be formed together with the plurality of bit lines 147. That is, the gate line 147P may have a stacked structure in which the first metal-based conductive pattern 145 and the second metal-based conductive pattern 146 are stacked. In order to be distinguished from the bit line structure 140 (which is constituted by the first metal-based conductive pattern 145, the second metal-based conductive pattern 146, and the insulating capping line 148), the first metal-based conductive pattern 145, the second metal-based conductive pattern 146, and the insulating capping line 148 that constitute the gate line structure 140P, may be referred to as a first metal-based peripheral conductive pattern, a second metal-based peripheral conductive pattern, and a peripheral insulating capping line, respectively.

A gate insulating layer pattern 142 may be disposed between the gate line 147P and the peripheral active region 117. In some embodiments, the gate line structure 140P may further include a conductive semiconductor pattern 132 disposed between the gate insulating layer pattern 142 and the first metal-based conductive pattern 145. The plurality of gate lines 147P may constitute the plurality of gate line patterns GLP illustrated in FIG. 2.

The gate insulating spacer 150P may include, for example, nitride. In some embodiments, the gate insulating spacer 150P may include a single layer but is not limited thereto and may have a plurality of stacked structures of a double layer or higher. In some embodiments, the gate insulating spacer 150P is formed together with the insulating spacer structure 150, and like the insulating spacer structure 150, the gate insulating spacer 150P may include the first insulating spacer 152, the second insulating spacer 154, and the third insulating spacer 156.

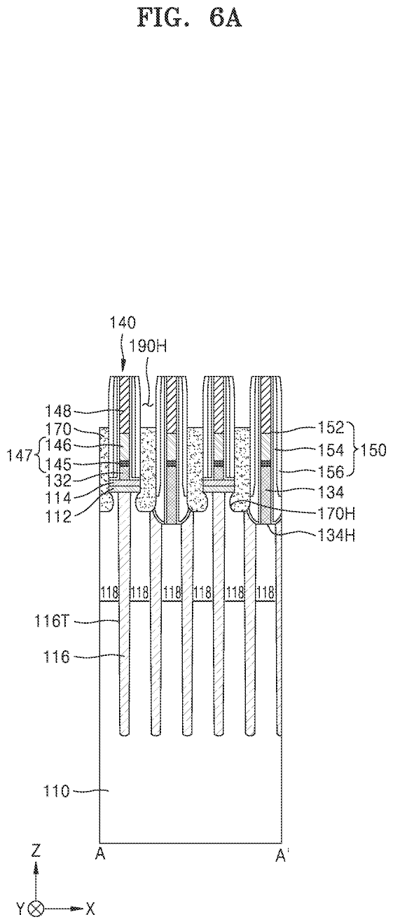

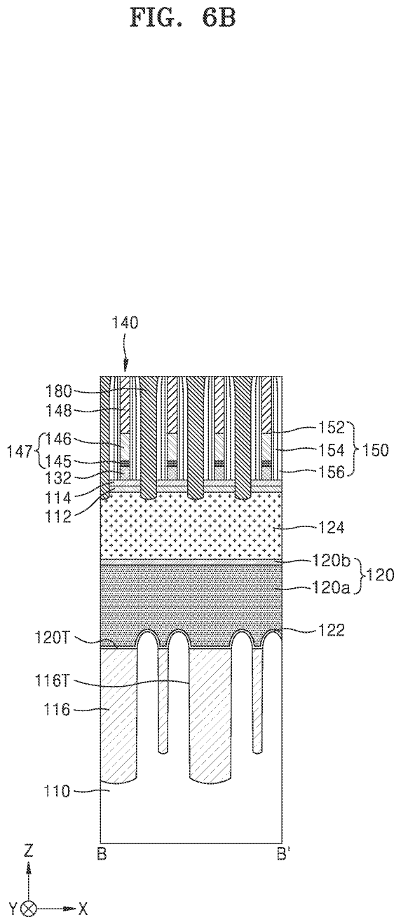

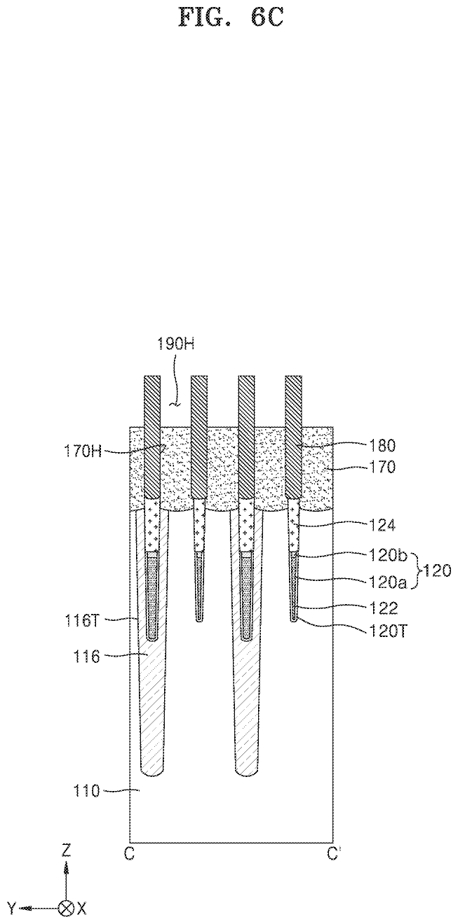

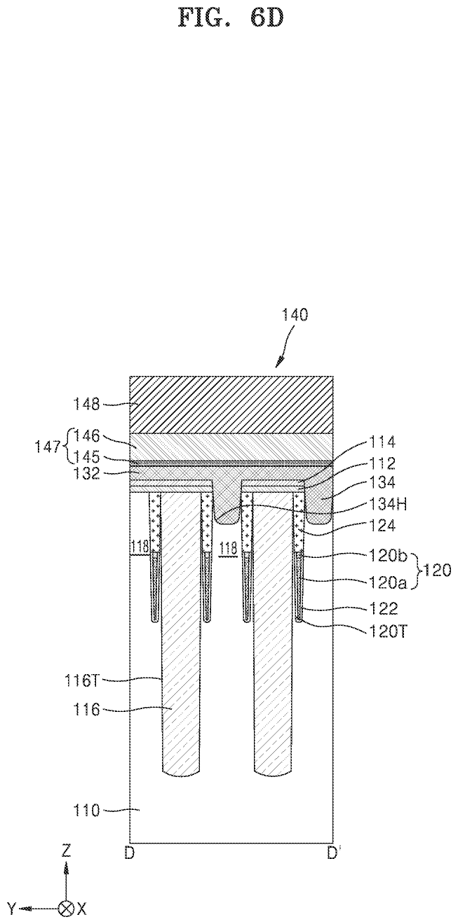

Referring to FIGS. 6A to 6D, in the memory cell region CR of FIG. 2, a plurality of buried contacts 170 and a plurality of insulating fences 180 may be formed in spaces between the plurality of insulating spacer structures 150 covering or at least partially covering both sidewalls of each of the plurality of bit line structures 140. The plurality of buried contacts 170 and the plurality of insulating fences 180 may be alternately disposed between a pair of insulating spacer structures 150 facing each other from among the plurality of insulating spacer structures 150 covering (or at least partially covering) both sidewalls of the plurality of bit line structures 140 (i.e., in the second horizontal direction (Y direction))). For example, the plurality of buried contacts 170 may include polysilicon. For example, the plurality of insulating fences 180 may include nitride.

In some embodiments, the plurality of buried contacts 170 may be arranged in a line in each of the first horizontal direction (X direction) and the second horizontal direction (Y direction). Each of the plurality of buried contacts 170 may extend from the active region 118 in a vertical direction (Z direction) perpendicular to the substrate 110. The plurality of buried contacts 170 may constitute the plurality of buried contacts BC illustrated in FIG. 2.

The plurality of buried contacts 170 may be disposed in a space defined by the plurality of insulating fences 180 and the plurality of insulating spacer structures 150 covering or at least partially covering both sidewalls of the plurality of bit line structures 140. The plurality of buried contacts 170 may fill or at least partially fill lower portions of spaces between the plurality of insulating spacer structures 150 covering (or at least partially covering) both sidewalls of each of the plurality of bit line structures 140.

A level of the top surfaces of the plurality of buried contacts 170 may be lower than a level of the top surfaces of the plurality of insulating capping lines 148. The top surfaces of the plurality of insulating fences 180 and the top surfaces of the plurality of insulating capping lines 148 may be at the same level in the vertical direction (Z direction).

A plurality of landing pad holes 190H may be defined by the plurality of insulating spacer structures 150 and the plurality of insulating fences 180. The plurality of buried contacts 170 may be exposed on the bottom surfaces of the plurality of landing pad holes 190H.

In the process of forming the plurality of buried contacts 170 and/or the plurality of insulating fences 180, an upper portion of the insulating capping line 148 included in the bit line structure 140 and an upper portion of the insulating spacer structure 150 may be removed and thus the level of the top surface of the bit line structure 140 may be lowered.

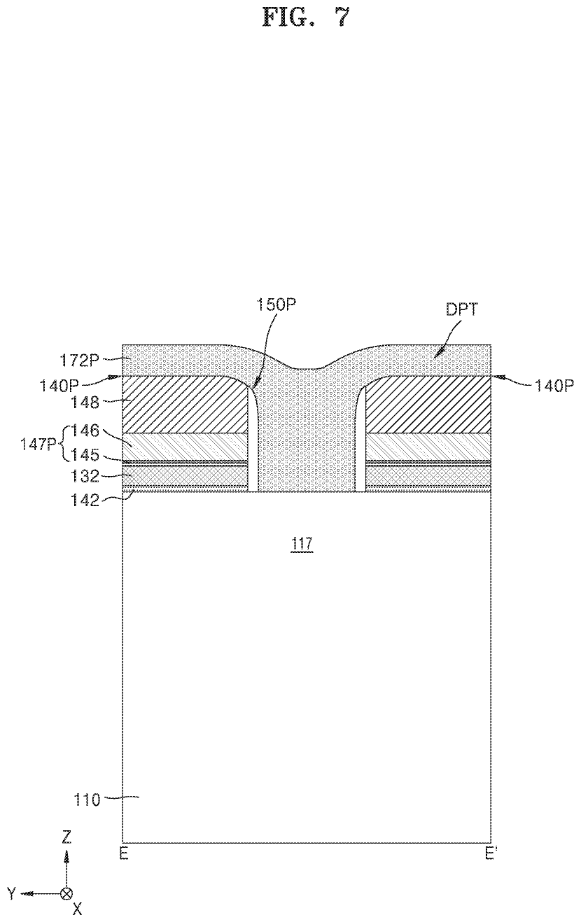

Referring to FIG. 7, a preliminary inter-gate insulating layer 172P covering (or at least partially covering) the plurality of gate line structures 140P and the plurality of gate insulating spacers 150P may be formed in the peripheral region PR. The preliminary inter-gate insulating layer 172P may fill or at least partially fill all spaces between the plurality of gate line structures 140P and the plurality of gate insulating spacers 150P, and may be formed to have a sufficient thickness to cover or at least partially cover the top surfaces of the plurality of insulating capping lines 148 of the plurality of gate line structures 140P. For example, the preliminary inter-gate insulating layer 172P may be formed such that a portion of the top surface of the preliminary inter-gate insulating layer 172P located at the lowest vertical level is at a higher vertical level than the top surface of each of the plurality of gate line structures 140P and the plurality of gate insulating spacers 150P.

The preliminary inter-gate insulating layer 172P may including an oxide containing an impurity DPT. For example, the preliminary inter-gate insulating layer 172P may include silicon oxide containing an impurity DPT. For example, the impurity DPT may be at least one of nitrogen (N), phosphorus (P), and carbon (C). Of the impurities DPT and oxygen (O) included in the preliminary inter-gate insulating layer 172P including oxide, an atomic ratio of the impurity DPT may be less than about 30%. For example, when the impurity DPT is nitrogen (N), an atomic ratio of nitrogen among nitrogen and oxygen included in the preliminary inter-gate insulating layer 172P may be about 10% to about 30%. For example, when the impurity DPT is phosphorus (P), an atomic ratio of phosphorus among phosphorus and oxygen included in the preliminary inter-gate insulating layer 172P may be about 1% to about 5%. For example, when the impurity DPT is carbon (C), an atomic ratio of carbon among carbon and oxygen included in the preliminary inter-gate insulating layer 172P may be about 1% to about 5%.

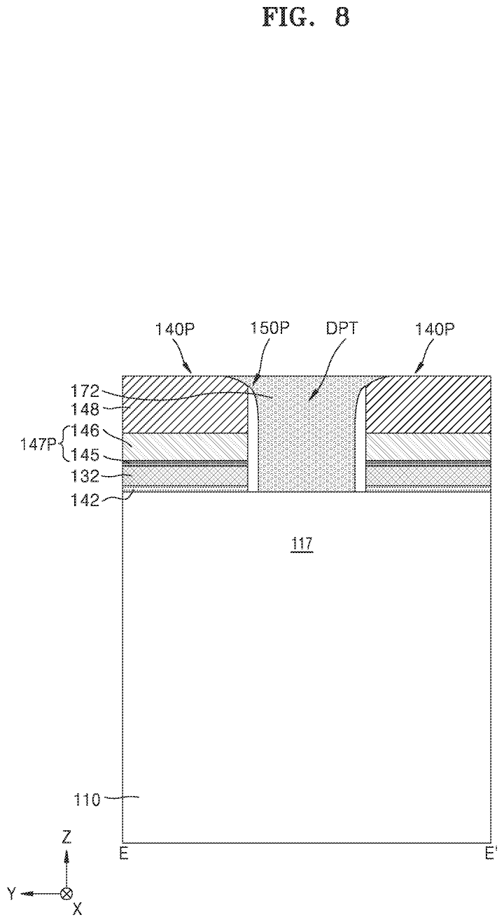

Referring to FIGS. 7 and 8, an upper portion of the preliminary inter-gate insulating layer 172P may be removed to form an inter-gate insulating layer 172. The inter-gate insulating layer 172 may be formed by removing an upper portion of the preliminary inter-gate insulating layer 172P to expose the plurality of gate line structures 140P. The inter-gate insulating layer 172 may fill or at least partially fill a space between the plurality of gate line structures 140P. In some embodiments, the top surfaces of the plurality of gate line structures 140P and the top surface of the inter-gate insulating layer 172 may be at the same vertical level to form a coplanar surface.

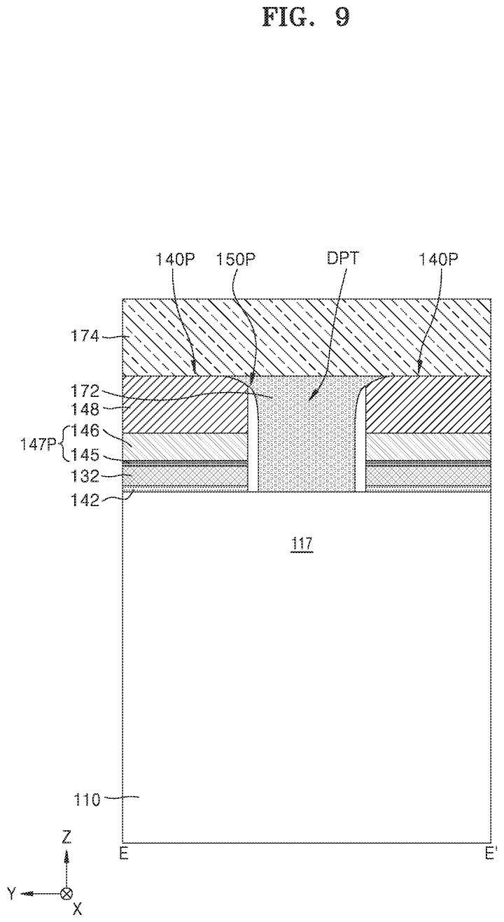

Referring to FIG. 9, a gate cover insulating layer 174 covering (or at least partially covering) the plurality of gate line structures 140P and the inter-gate insulating layer 172 may be formed. The gate cover insulating layer 174 may include a material that is different from that of the inter-gate insulating layer 172. The gate cover insulating layer 174 may include nitride. For example, the gate cover insulating layer 174 may include silicon nitride.

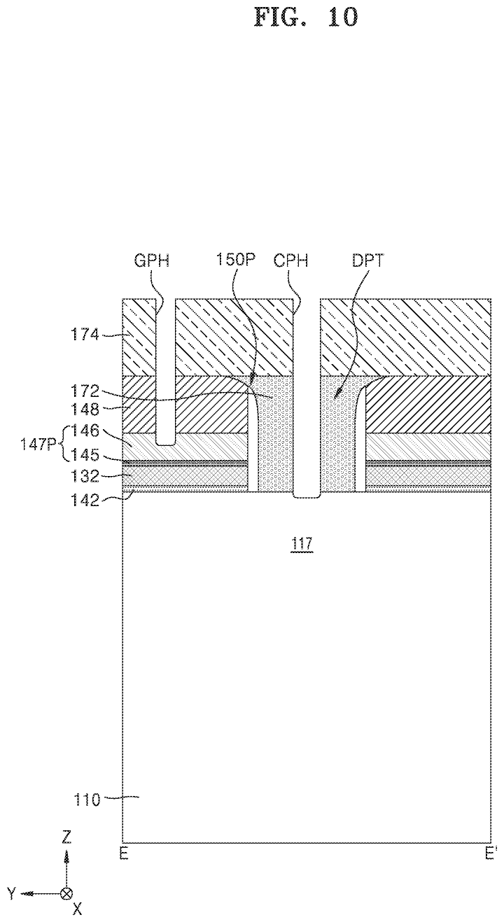

Referring to FIG. 10, a first peripheral contact hole CPH passing through the gate cover insulating layer 174 and the inter-gate insulating layer 172, and a second peripheral contact hole GPH passing through the gate cover insulating layer 174 and the insulating capping line 148 of the gate line structure 140P, may be formed. The peripheral active region 117 of the substrate 110 may be exposed on the bottom of the first peripheral contact hole CPH, and the gate line 147P may be exposed on the bottom of the second peripheral contact hole GPH.

The first peripheral contact hole CPH may be formed by removing a portion of the gate cover insulating layer 174 and a portion of the inter-gate insulating layer 172 to pass through the gate cover insulating layer 174 and the inter-gate insulating layer 172. In some embodiments, the first peripheral contact hole CPH may extend into the peripheral active region 117 through the gate cover insulating layer 174 and the inter-gate insulating layer 172. The second peripheral contact hole GPH may be formed to remove a portion of the gate cover insulating layer 174 and a portion of the insulating capping line 148 of the gate line structure 140P to pass through the gate cover insulating layer 174 and the insulating capping line 148 of the gate line structure 140P. In some embodiments, the second peripheral contact hole GPH may be formed to extend into the gate line 147P through both the gate cover insulating layer 174 and the insulating capping line 148 of the gate line structure 140P.

The first peripheral contact hole CPH may be formed such that an inner surface of the first peripheral contact hole CPH extends in the vertical direction (Z direction) or extends in the vertical direction (Z direction) with a constant inclination with respect to the vertical direction (Z direction). For example, the inner surface of the first peripheral contact hole CPH may extend in the vertical direction (Z direction) or extend in the vertical direction (Z direction) while having a constant inclination of less than about 5° with respect to the vertical direction (Z direction). For example, the first peripheral contact hole CPH may have a substantially constant horizontal width and extend in the vertical direction (Z direction). For example, the first peripheral contact hole CPH may extend toward the peripheral active region 117 of the substrate 110 and may have a substantially uniformly decreasing horizontal width.

When each of the gate cover insulating layer 174 and the inter-gate insulating layer 172 includes nitride, and oxide containing no impurities DPT, in the process of removing a portion of the gate cover insulating layer 174 and a portion of the inter-gate insulating layer 172 to form the first peripheral contact hole CPH, the removal rate of the inter-gate insulating layer 172 may be faster than the removal rate of the gate cover insulating layer 174. In this case, the horizontal width of the first peripheral contact hole CPH may be relatively large in the inter-gate insulating layer 172.

However, because the inter-gate insulating layer 172 according to some embodiments includes the impurity DPT, the inter-gate insulating layer 172 may be removed at a removal rate similar to that of the gate cover insulating layer 174, thereby preventing or reducing the occurrence of a bowing phenomenon in which the horizontal width of the first peripheral contact hole CPH becomes relatively large in the inter-gate insulating layer 172.

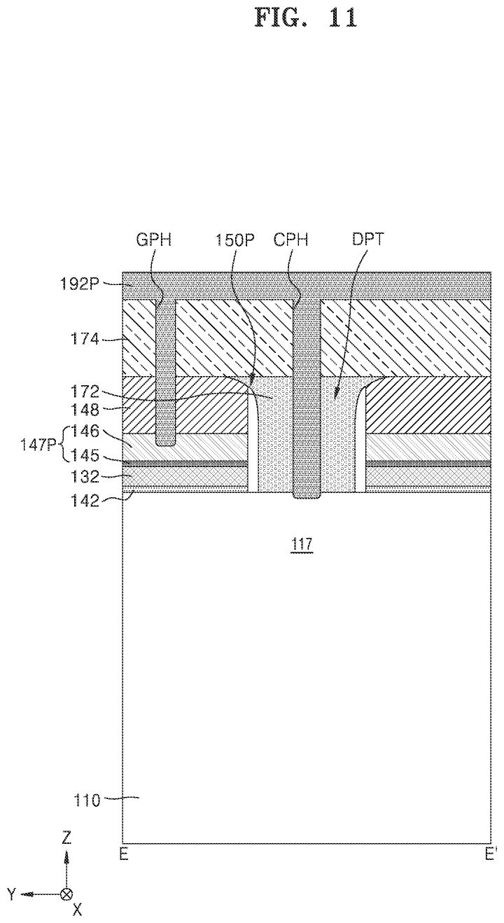

Referring to FIG. 11, a preliminary contact material layer 192P may be formed to cover or at least partially cover the top surface of the gate cover insulating layer 174 while filling or at least partially filling the first peripheral contact hole CPH and the second peripheral contact hole GPH. The preliminary contact material layer 192P may include metal or a conductive metal compound. For example, the preliminary contact material layer 192P may include tungsten (W).

In some embodiments, a metal silicide layer may be formed on the peripheral active region 117 before forming the preliminary contact material layer 192P. The metal silicide layer may be disposed between the plurality of peripheral active regions 117 and the preliminary contact material layer 192P. The metal silicide layer may include tungsten silicide (WSiₓ), cobalt silicide (CoSiₓ), nickel silicide (NiSiₓ), or manganese silicide (MnSiₓ) but is not limited thereto.

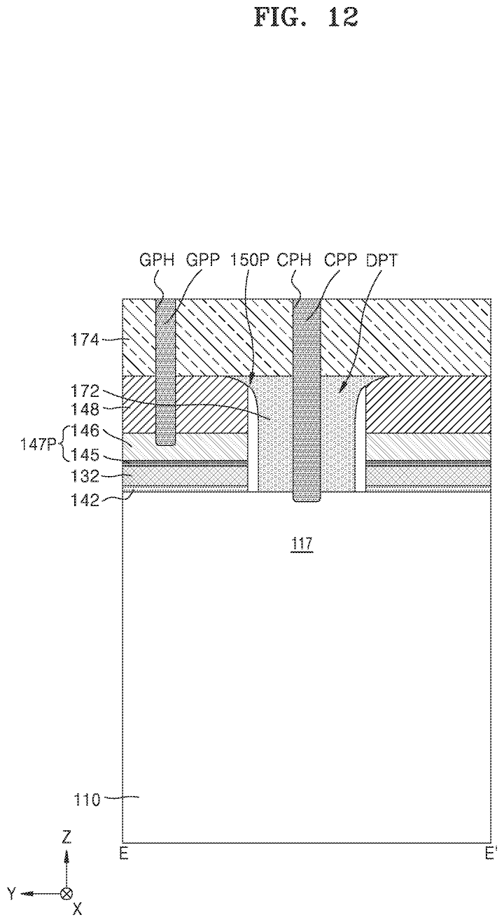

Referring to FIGS. 11 and 12, a first peripheral contact plug CPP and a second peripheral contact plug GPP may be formed by removing an upper portion of the preliminary contact material layer 192P. The first peripheral contact plug CPP and the second peripheral contact plug GPP may be formed by removing an upper portion of the preliminary contact material layer 192P to expose the gate cover insulating layer 174. In some embodiments, the top surface of the first peripheral contact plug CPP, the top surface of the second peripheral contact plug GPP, and the top surface of the gate cover insulating layer 174 may be at the same vertical level to form a coplanar surface. The first peripheral contact plug CPP and the second peripheral contact plug GPP may respectively be the first peripheral contact plug CPP and the second peripheral contact plug GPP shown in FIG. 2. The first peripheral contact plug CPP may be connected to the peripheral active region 117 and the second peripheral contact plug GPP may be connected to the gate line 147P.

The first peripheral contact plug CPP may be formed such that an outer surface of the first peripheral contact plug CPP extends in the vertical direction (Z direction) or extends in the vertical direction (Z direction) with a constant inclination with respect to the vertical direction (Z direction). For example, the outer surface of the first peripheral contact plug CPP may extend in the vertical direction (Z direction) or extend in the vertical direction (Z direction) while having a constant inclination of less than 5° with respect to the vertical direction (Z direction). For example, the first peripheral contact plug CPP may have a substantially constant horizontal width and extend in the vertical direction (Z direction). For example, the first peripheral contact plug CPP may extend toward the peripheral active region 117 of the substrate 110 and may have a substantially uniformly decreasing horizontal width.

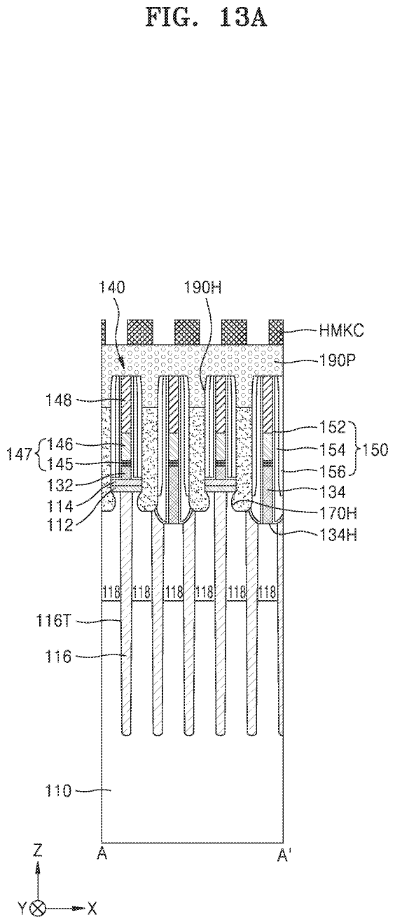

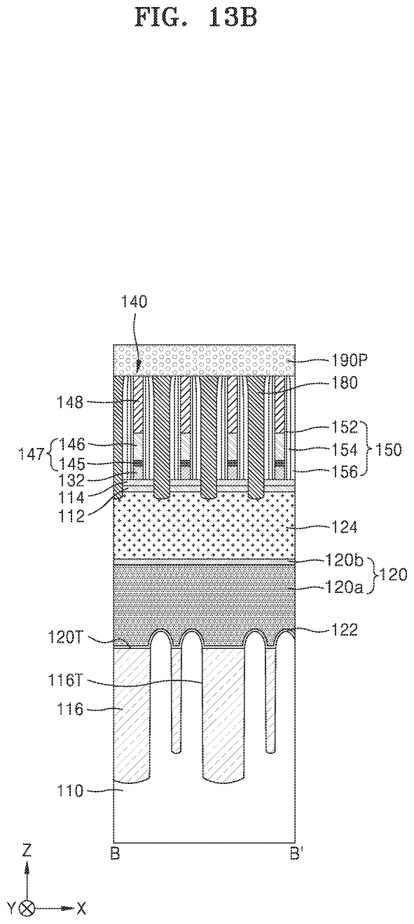

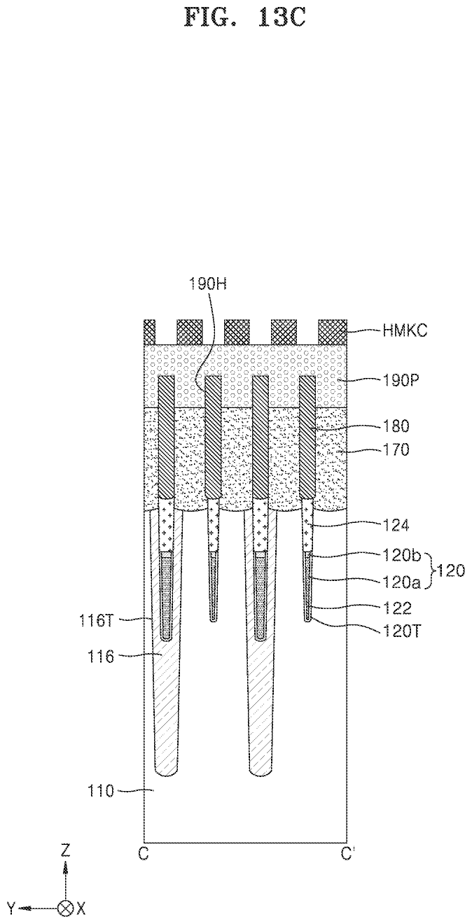

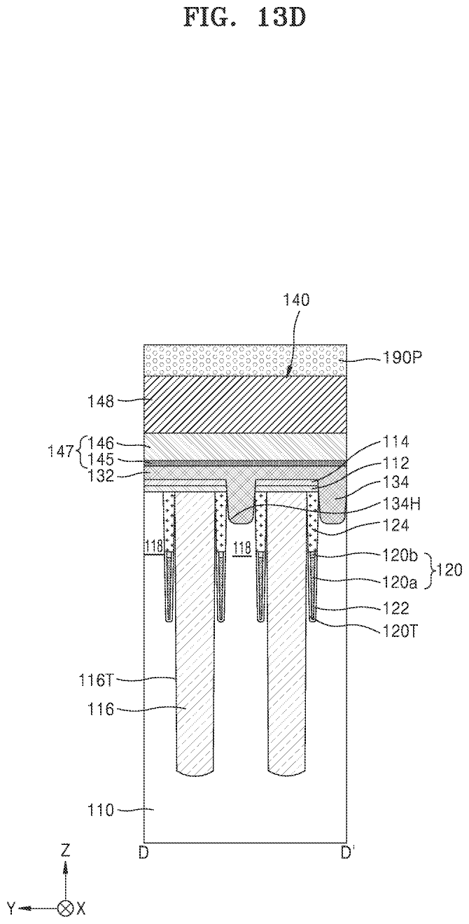

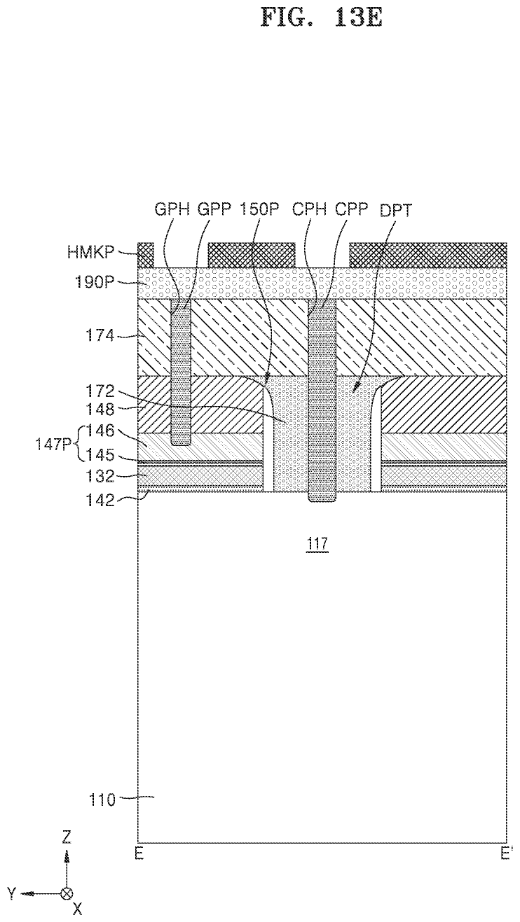

Referring to FIGS. 13A to 13E, a landing pad material layer 190P may be formed. The landing pad material layer 190P may fill or at least partially fill the plurality of landing pad holes 190H. The landing pad material layer 190P may cover or at least partially cover the plurality of bit line structures 140 in the memory cell region CR (see FIG. 2) and may cover or at least partially cover the first peripheral contact plug CPP, the second peripheral contact plug GPP, and the gate cover insulating layer 174 in the peripheral region PR (see FIG. 2). In some embodiments, an interface where the buried contact 170 and the landing pad material layer 190P contact each other may be higher than a vertical level of the top surface of the second metal-based conductive pattern 146 and be lower than a vertical level of the top surface of the insulating capping line 148. In some embodiments, the landing pad material layer 190P may include a conductive barrier layer and a conductive pad material layer on the conductive barrier layer. For example, the conductive barrier layer may include metal, conductive metal nitride, or a combination thereof. In some embodiments, the conductive barrier layer may have a Ti/TiN stack structure. In some embodiments, the conductive pad material layer may include tungsten (W).

In some embodiments, a metal silicide layer may be formed on the plurality of buried contacts 170 before forming the landing pad material layer 190P. The metal silicide layer may be disposed between the plurality of buried contacts 170 and the landing pad material layer 190P. The metal silicide layer may include cobalt silicide (CoSiₓ), nickel silicide (NiSiₓ), or manganese silicide (MnSiₓ) but is not limited thereto.

A plurality of hard mask patterns HMKC and HMKP may be formed on the landing pad material layer 190P. In some embodiments, the plurality of hard mask patterns HMKC and HMKP may be formed through an EUV lithography process. The plurality of hard mask patterns HMKC and HMKP may include a cell hard mask pattern HMKC formed in the memory cell region CR in FIG. 2 and a peripheral hard mask pattern HMKP formed in the peripheral region PR in FIG. 2.

The peripheral hard mask pattern HMKP may be formed so as not to overlap each of the first peripheral contact plug CPP and the second peripheral contact plug GPP in the vertical direction (Z direction).

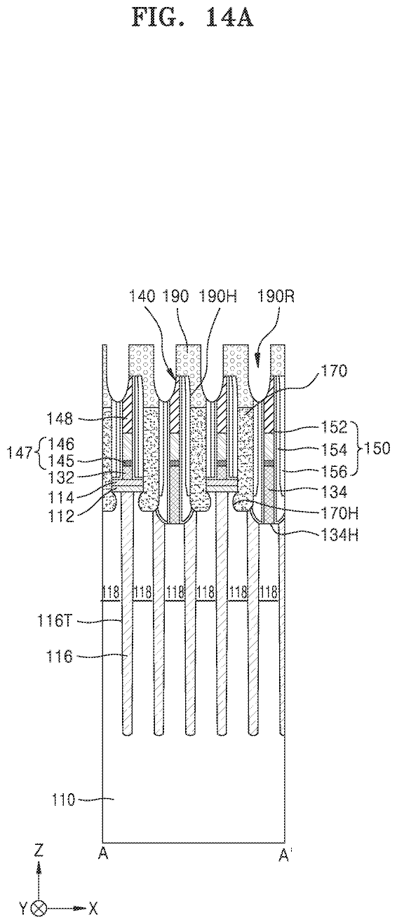

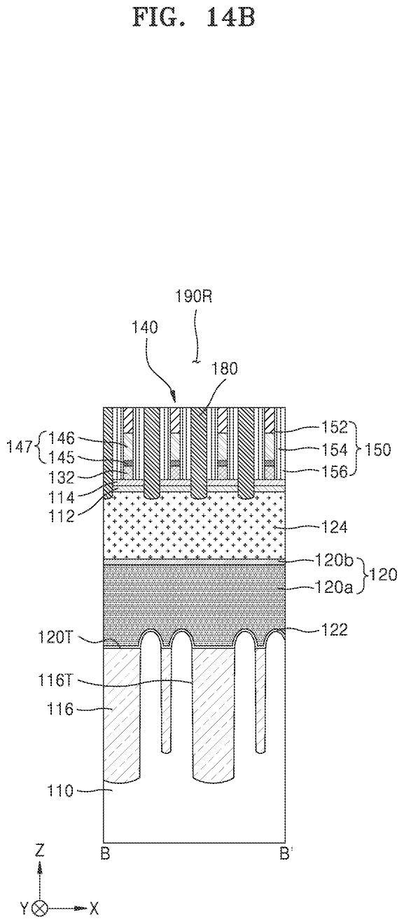

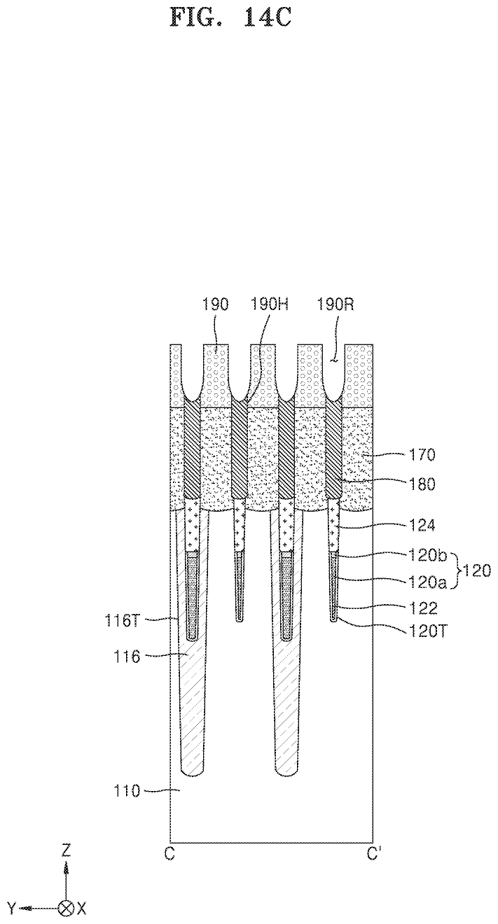

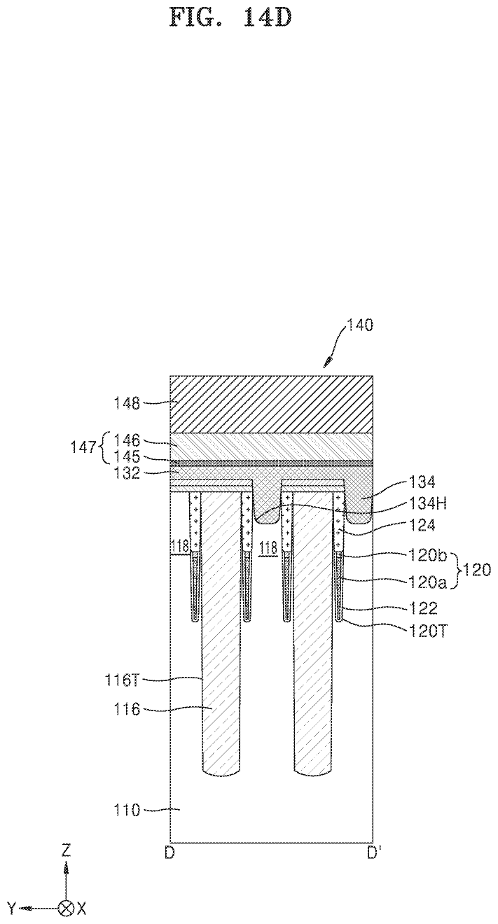

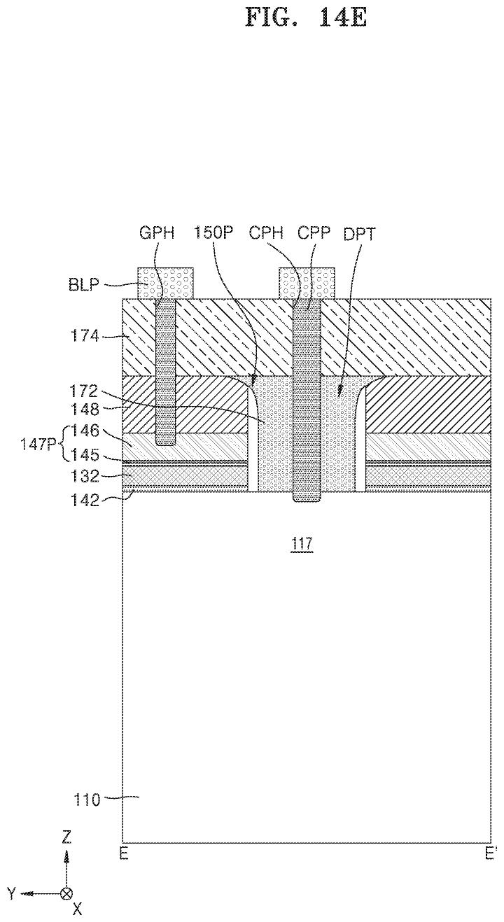

Referring to FIGS. 13A to 13E and FIGS. 14A to 14E, by removing a portion of the landing pad material layer 190P using the cell hard mask pattern HMKC and the peripheral hard mask pattern HMKP as an etching mask, a plurality of landing pads 190 (which fill at least portions of the plurality of landing pad holes 190H, extend onto the plurality of bit line structures 140, and are separated into a plurality by a recess portion 190R) may be formed in the memory cell region CR (see FIG. 2) and a plurality of peripheral bit lines BLP may be formed in the peripheral region PR (see FIG. 2).

The plurality of landing pads 190 may be spaced apart from each other with the recess portion 190R therebetween. The plurality of landing pads 190 may be disposed on the plurality of buried contacts 170 and may extend onto the plurality of bit line structures 140. In some embodiments, the plurality of landing pads 190 may extend onto the plurality of bit lines 147. The plurality of landing pads 190 may be disposed on the plurality of buried contacts 170, and thus, the plurality of buried contacts 170 may be electrically connected to the plurality of landing pads 190 corresponding thereto. The plurality of landing pads 190 may be connected to the active region 118 through the plurality of buried contacts 170. The plurality of landing pads 190 may constitute the plurality of landing pads LP illustrated in FIG. 2.

The buried contact 170 may be disposed between two adjacent bit line structures 140, and the landing pad 190 may extend onto one bit line structure 140 from among two bit line structures 140 adjacent to each other with the buried contact 170 therebetween.

Each of the first peripheral contact plug CPP and the second peripheral contact plug GPP may be connected to any one of the plurality of peripheral bit lines BLP.

Referring to FIGS. 15A to 15E, a semiconductor device 1 including a plurality of capacitor structures 200 may be formed by sequentially forming a capacitor dielectric layer 220 and an upper electrode 230 on a plurality of lower electrodes 210. The plurality of capacitor structures 200 may include the plurality of lower electrodes 210, the capacitor dielectric layer 220, and the upper electrode 230.

Each of the plurality of lower electrodes 210 may be electrically connected to each of the plurality of landing pads 190. Each of the plurality of lower electrodes 210 may have a column shape filled or at least partially filled inside to have a circular horizontal cross-section (that is, a pillar shape), but is not limited thereto. In some embodiments, each of the plurality of lower electrodes 210 may have a cylindrical shape with a lower portion closed. In some embodiments, the plurality of lower electrodes 210 may be arranged in a honeycomb arrangement in a zigzag pattern with respect to the first horizontal direction (X direction) or the second horizontal direction (Y direction). In some other embodiments, the plurality of lower electrodes 210 may be arranged in a matrix form arranged in a row in each of the first horizontal direction (X direction) and the second horizontal direction (Y direction). The plurality of lower electrodes 210 may include, for example, silicon doped with impurities, a metal, such as tungsten or copper, or a conductive metal compound, such as titanium nitride. The lower electrode 210 may be the storage node SN shown in FIG. 2.

The capacitor dielectric layer 220 may conformally cover surfaces of the plurality of lower electrodes 210. In some embodiments, the capacitor dielectric layer 220 may be integrally formed to cover or at least partially cover the plurality of lower electrodes 210 in a predetermined region (e.g., in one memory cell region CR (see FIG. 2)). The capacitor dielectric layer 220 may include, for example, TaO, TaAlO, TaON, AlO, AlSiO, HfO, HfSiO, ZrO, ZrSiO, TiO, TiAlO, BST((Ba,Sr)TiO), STO(SrTiO), BTO(BaTiO), PZT(Pb,Zr,Ti)O), (Pb,La)(Zr,Ti)O, Ba(Zr,Ti)O, Sr(Zr,Ti)O, or a combination thereof.

The upper electrode 230 may include, for example, W, Ru, RuO, Pt, PtO, Ir, IrO, SRO(SrRuO), BSRO((Ba,Sr)RuO), CRO(CaRuO), BaRuO, La(Sr, Co)O, or the like. In some embodiments, the upper electrode 230 may include a metal material. For example, the upper electrode 230 may include W.

Before forming the plurality of capacitor structures 200, an insulating structure 195 filling or at least partially filling the recess portion 190R may be formed. In some embodiments, the insulating structure 195 may include an interlayer insulating layer and an etch stop layer. For example, the interlayer insulating layer may include oxide and the etch stop layer may include nitride. Although FIGS. 15A and 15C illustrate that the top surface of the insulating structure 195 and the top surface of the landing pad 190 are at the same level, the disclosure is not limited thereto.

In the peripheral region PR (see FIG. 2), a peripheral bit line insulating structure BPS between the plurality of peripheral bit lines BLP may be formed. In some embodiments, the top surface of the peripheral bit line insulating structure BPS and the top surface of the peripheral bit line BLP may be at the same level. In some embodiments, the insulating structure 195 and the peripheral bit line insulating structure BPS may be formed by forming a preliminary insulating material layer and then removing an upper portion of the preliminary insulating material layer to expose the plurality of landing pads 190 and the plurality of peripheral bit lines BLP. The preliminary insulating material layer may fill or at least partially fill a space between the recess portion 190R and the plurality of peripheral bit lines BLP and may cover or at least partially cover the plurality of landing pads 190 and the plurality of peripheral bit lines BLP. For example, the insulating structure 195 and the peripheral bit line insulating structure BPS may include the same material.

A buried insulating layer 250 may be formed in the peripheral region PR (see FIG. 2) to cover or at least partially cover the plurality of peripheral bit lines BLP and the peripheral bit line insulating structure BPS. The buried insulating layer 250 may be formed to be filled at substantially the same or similar vertical level as the plurality of capacitor structures 200 in the peripheral region PR where the plurality of capacitor structures 200 are not formed. The buried insulating layer 250 may include, for example, an oxide or an ultra-low K (ULK) material. The oxide may include any one selected from BoroPhosphoSilicate Glass (BPSG), PhosphoSilicate Glass (PSG), BoroSilicate Glass (BSG), Un-doped Silicate Glass (USG), Tetra Ethyle Ortho Silicate (TEOS), and High Density Plasma (HDP). The ULK material may include, for example, one of SiOC and SiCOH having an ultra-low dielectric constant K of about 2.2 to about 2.4.

The semiconductor device 1 may include a substrate 110 in which a plurality of active regions 118 are defined in the memory cell region CR, and a plurality of gate dielectric layers 122, a plurality of word lines 120, and a plurality of buried insulating layers 124 sequentially formed inside the plurality of word line trenches 120T crossing the plurality of active regions 118 in the substrate 110. The semiconductor device 1 may include a first insulating layer pattern 112 covering or at least partially covering the isolation layer 116, the plurality of active regions 118, and the plurality of buried insulating layers 124. The semiconductor device 1 may include a second insulating layer pattern 114 on the first insulating layer pattern 112, a plurality of bit line structures 140 on the second insulating layer pattern 114, and a plurality of insulating spacer structures 150 covering or at least partially covering both sidewalls of the plurality of bit line structures 140. The semiconductor device 1 may include a plurality of buried contacts 170 filling or at least partially filling a lower portion of a space defined by the plurality of insulating fences 180 and the plurality of insulating spacer structures 150 and connected to the plurality of active regions 118. The semiconductor device 1 may include a plurality of landing pads 190 filling or at least partially filling an upper portion of the space and extending to an upper portion of the bit line structure 140, and a plurality of capacitor structures 200 including a plurality of lower electrodes 210 connected to the plurality of landing pads 190, a capacitor dielectric layer 220, and an upper electrode 230. The semiconductor device 1 may include a substrate 110 in which a peripheral active region 117 is defined in the peripheral region PR, a plurality of gate line structures 140P on the peripheral active region 117 on the substrate 110, a gate insulating layer pattern 142 between the gate line 147P and the peripheral active region 117, an inter-gate insulating layer 172 between the plurality of gate line structures 140P, a gate cover insulating layer 174 covering or at least partially covering the plurality of gate line structures 140P and the inter-gate insulating layer 172, a first peripheral contact plug CPP filling or at least partially filling the first peripheral contact hole CPH passing through the gate cover insulating layer 174 and the inter-gate insulating layer 172, a second peripheral contact plug GPP filling or at least partially filling the second peripheral contact hole GPH passing through the gate cover insulating layer 174 and the insulating capping line 148 of the gate line structure 140P, and a plurality of peripheral bit lines BLP connected to the first peripheral contact plug CPP and the second peripheral contact plug GPP.

In some embodiments, the top surface of the bit line 147 and the top surface of the gate line 147P may be at the same first vertical level LV1, but are not limited thereto. For example, the top surface of the bit line 147 and the top surface of the gate line 147P may be at different vertical levels. In some embodiments, the top surface of the landing pad 190 and the top surface of the peripheral bit line BLP may be at the same second vertical level LV2 but are not limited thereto. For example, the top surface of the landing pad 190 and the top surface of the peripheral bit line BLP may be at different vertical levels.

In the semiconductor device 1 according to some embodiments, because the inter-gate insulating layer 172 includes the impurity DPT, the occurrence of a bowing phenomenon, in which the horizontal width of the first peripheral contact hole CPH becomes relatively large in the inter-gate insulating layer 172, may be prevented or reduced. Therefore, the occurrence of a void in the first peripheral contact plug CPP filling or at least partially filling the first peripheral contact hole CPH may be prevented, thereby securing connection reliability between components of the semiconductor device 1.

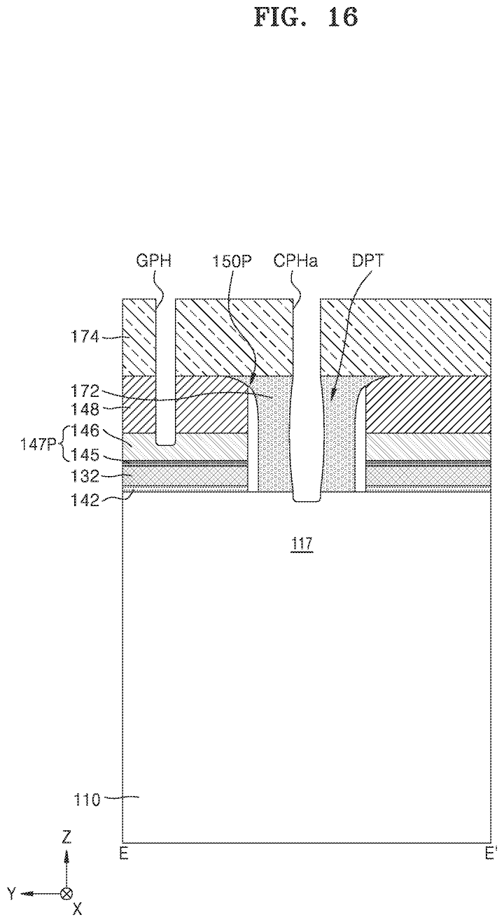

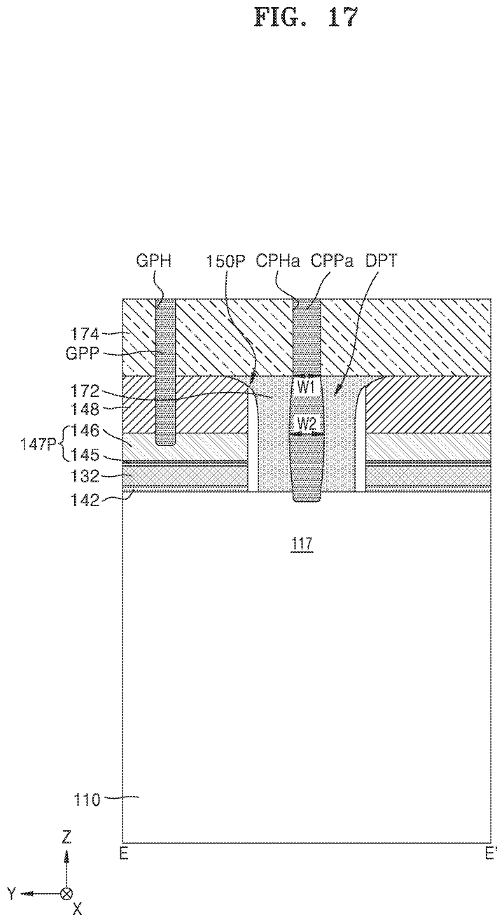

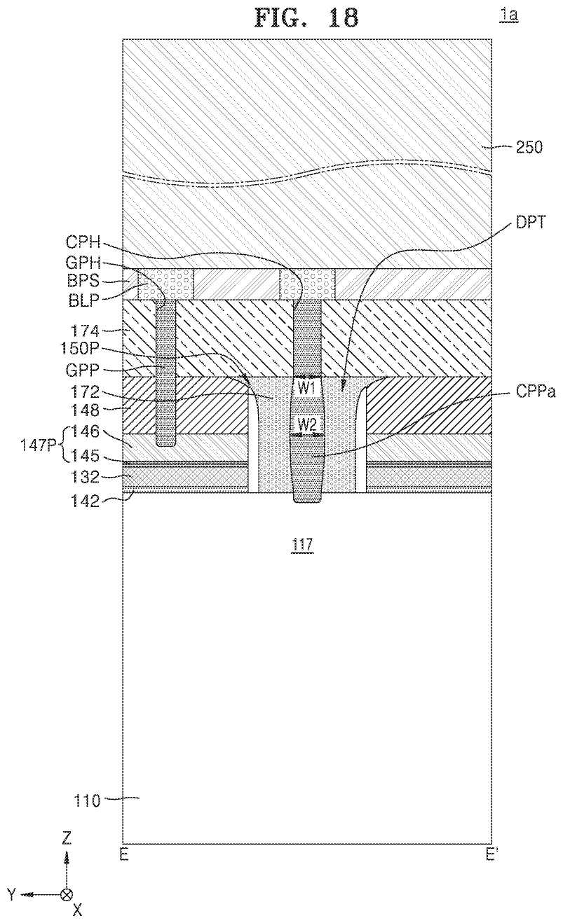

FIGS. 16 and 17 are cross-sectional views illustrating a method of manufacturing a semiconductor device, according to embodiments. FIG. 18 is a cross-sectional view illustrating a semiconductor device according to embodiments. Specifically, FIGS. 16 to 18 are cross-sectional views taken along line E-E′ in FIG. 2.

Referring to FIG. 16, a first peripheral contact hole CPHa passing through the gate cover insulating layer 174 and the inter-gate insulating layer 172, and a second peripheral contact hole GPH passing through the gate cover insulating layer 174 and the insulating capping line 148 of the gate line structure 140P may be formed. The peripheral active region 117 of the substrate 110 may be exposed on the bottom of the first peripheral contact hole CPHa, and the gate line 147P may be exposed on the bottom of the second peripheral contact hole GPH. The first peripheral contact hole CPHa may be formed by removing a portion of the gate cover insulating layer 174 and a portion of the inter-gate insulating layer 172 to pass through the gate cover insulating layer 174 and the inter-gate insulating layer 172. In some embodiments, the first peripheral contact hole CPHa may extend into the peripheral active region 117 through the gate cover insulating layer 174 and the inter-gate insulating layer 172.

The first peripheral contact hole CPHa may have a relatively large horizontal width due to bowing at a portion passing through the inter-gate insulating layer 172. For example, a portion passing through the inter-gate insulating layer 172, of a space defined by the first peripheral contact hole CPHa, may have an entasis shape in which the horizontal width of a middle portion is greater than the horizontal width of each of upper and lower portions. Compared to the minimum horizontal width of the first peripheral contact hole CPHa, the maximum horizontal width of the first peripheral contact hole CPHa may be greater than 100% and less than 110%.

Referring to FIG. 17, similar to that described with reference to FIGS. 11 and 12, after forming a preliminary contact material layer filling or at least partially filling the first peripheral contact hole CPHa and the second peripheral contact hole GPH and covering or at least partially covering the top surface of the gate cover insulating layer 174, an upper portion of the preliminary contact material layer may be removed to form a first peripheral contact plug CPPa and a second peripheral contact plug GPP. In some embodiments, the top surface of the first peripheral contact plug CPPa, the top surface of the second peripheral contact plug GPP, and the top surface of the gate cover insulating layer 174 may be at the same vertical level to form a coplanar surface. The first peripheral contact plug CPPa and the second peripheral contact plug GPP may respectively be the first peripheral contact plug CPP and the second peripheral contact plug GPP shown in FIG. 2.

The first peripheral contact plug CPPa may have a relatively large horizontal width due to bowing at a portion passing through the inter-gate insulating layer 172. For example, a portion passing through the inter-gate insulating layer 172, of the first peripheral contact plug CPPa, may have an entasis shape in which the horizontal width of a middle portion is greater than the horizontal width of each of upper and lower portions. Compared to a minimum horizontal width W1 of the first peripheral contact plug CPPa, the maximum horizontal width of the first peripheral contact plug CPPa may be greater than about 100% and less than about 110%.

Referring to FIG. 18, a semiconductor device 1a may be formed with reference to that illustrated in FIGS. 13A to 15E. Cross-sectional views of the semiconductor device 1a corresponding to lines A-A′, B-B′, C-C′, and D-D′ in FIG. 2 are substantially the same as those shown in FIGS. 15A to 15D.

In the semiconductor device 1a according to some embodiments, because the inter-gate insulating layer 172 includes the impurity DPT, a bowing phenomenon in which the horizontal width of the first peripheral contact hole CPHa becomes relatively large in the inter-gate insulating layer 172 may be reduced. Therefore, the occurrence of a void in the first peripheral contact plug CPPa filling or at least partially filling the first peripheral contact hole CPHa may be prevented, thereby securing connection reliability between components of the semiconductor device 1a.

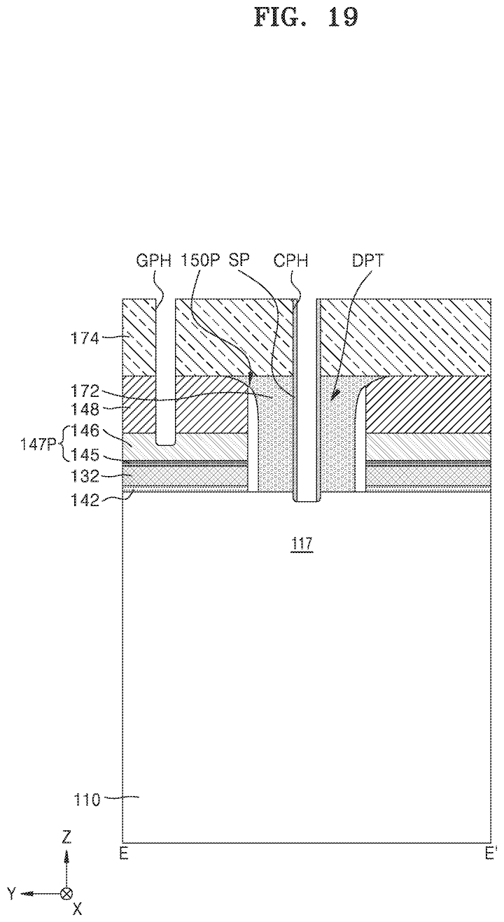

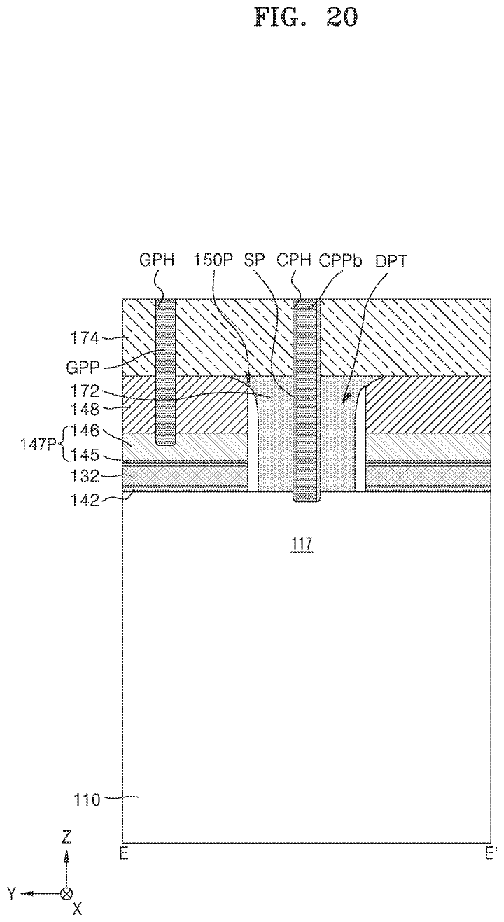

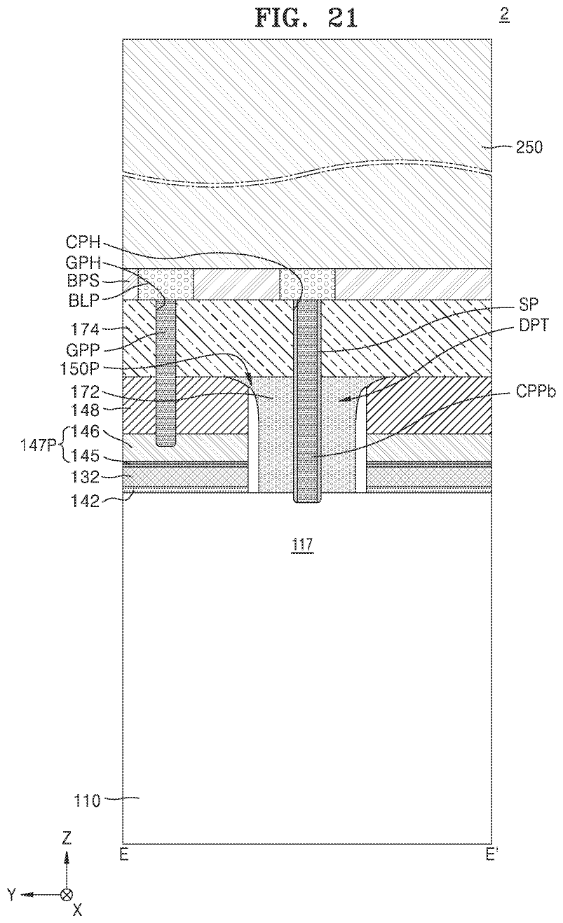

FIGS. 19 and 20 are cross-sectional views illustrating a method of manufacturing a semiconductor device, according to embodiments. FIG. 21 is a cross-sectional view illustrating a semiconductor device according to embodiments. Specifically, FIGS. 19 to 21 are cross-sectional views taken along line E-E′ in FIG. 2.

Referring to FIG. 19, after forming a first peripheral contact hole CPH and a second peripheral contact hole GPH as described with reference to FIG. 10, a contact spacer SP covering or at least partially covering the inner surface of the first peripheral contact hole CPH may be formed. The contact spacer SP may be formed to conformally cover an inner wall of the first peripheral contact hole CPH. For example, the contact spacer SP may include nitride.

Referring to FIG. 20, a first peripheral contact plug CPPb filling or at least partially filling the first peripheral contact hole CPH, of which the inner surface is covered or at least partially covered by the contact spacer SP, and a second peripheral contact plug GPP filling or at least partially filling the second peripheral contact hole GPH may be formed. The first peripheral contact plug CPPb may be apart from an inter-gate insulating layer 172 and a gate cover insulating layer 174 with the contact spacer SP therebetween. The contact spacer SP may surround or at least partially surround an outer surface of the first peripheral contact plug CPPb.

Referring to FIG. 21, a semiconductor device 2 may be formed with reference to that illustrated in FIGS. 13A to 15E. Cross-sectional views of the semiconductor device 2 corresponding to lines A-A′, B-B′, C-C′, and D-D′ in FIG. 2 are substantially the same as those shown in FIGS. 15A to 15D.

In the semiconductor device 2 according to some embodiments, because the contact spacer SP covers or at least partially covers the inner surface of the first peripheral contact hole CPH, the first peripheral contact plug CPPb filling (or at least partially filling) the first peripheral contact hole CPH may have substantially the same horizontal width and extend in the vertical direction (Z direction). Accordingly, the occurrence of a void in the first peripheral contact plug CPPb may be prevented, thereby securing connection reliability between components of the semiconductor device 2.

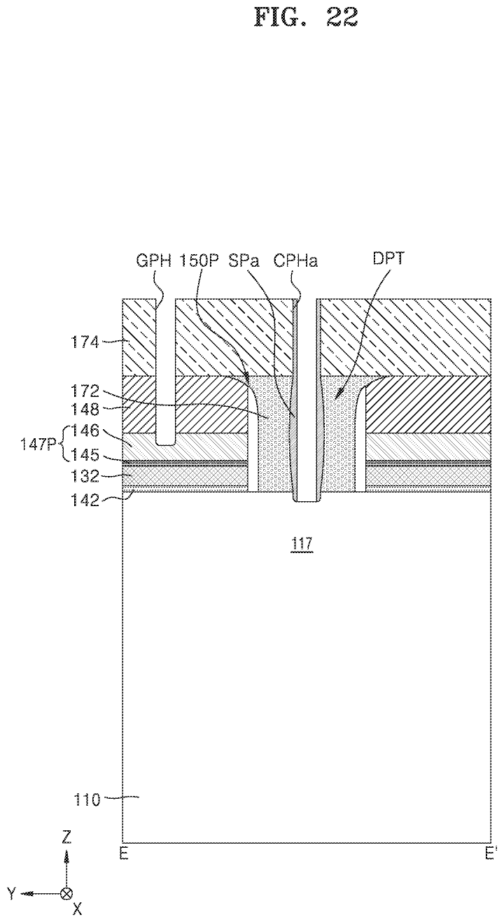

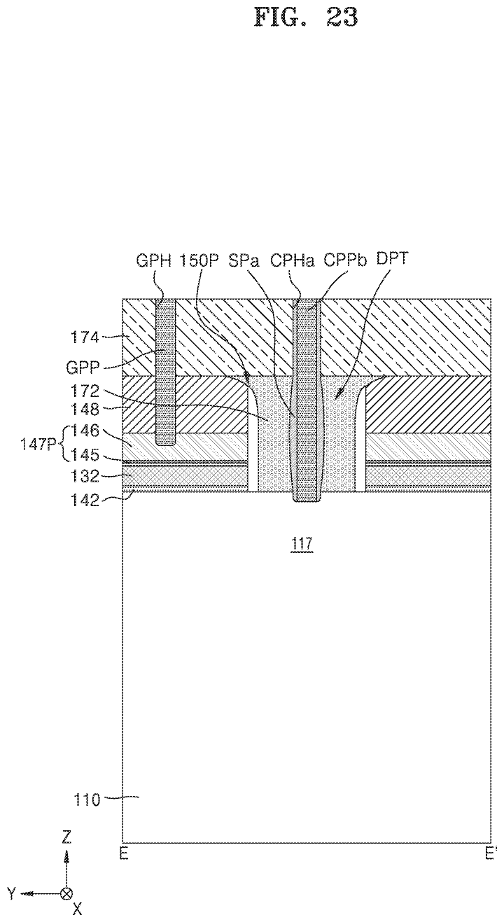

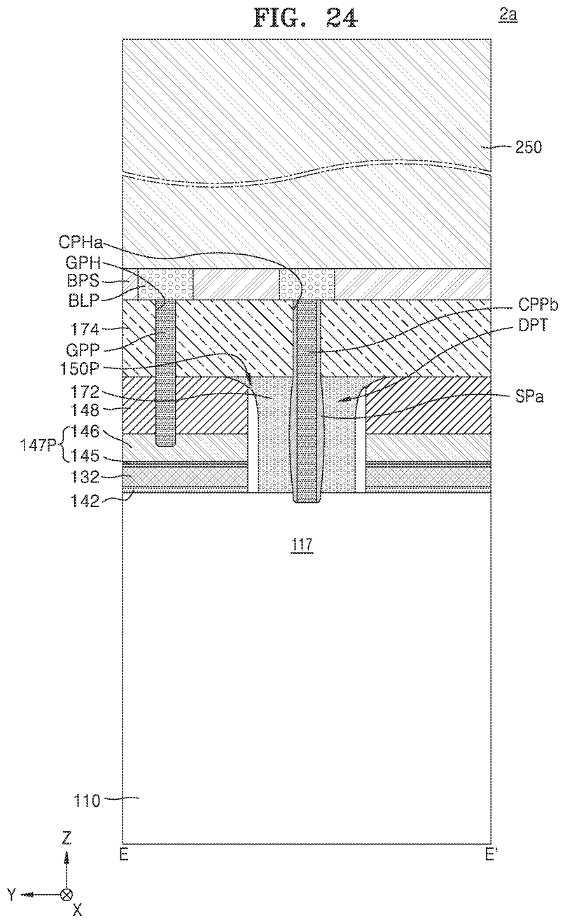

FIGS. 22 and 23 are cross-sectional views illustrating a method of manufacturing a semiconductor device, according to embodiments. FIG. 24 is a cross-sectional view illustrating a semiconductor device according to embodiments. Specifically, FIGS. 22 to 24 are cross-sectional views taken along lines E-E′ in FIG. 2.

Referring to FIG. 22, after forming a first peripheral contact hole CPHa and a second peripheral contact hole GPH as described with reference to FIG. 16, a contact spacer SPa covering or at least partially covering the inner surface of the first peripheral contact hole CPHa may be formed. In the first peripheral contact hole CPHa, the horizontal width of a space defined by the contact spacer SPa may have substantially the same horizontal width and may extend in the vertical direction (Z direction). For example, the contact spacer SPa may include nitride.

Referring to FIG. 23, a first peripheral contact plug CPPb filling or at least partially filling the first peripheral contact hole CPHa, of which the inner surface is covered or at least partially covered by the contact spacer SPa, and a second peripheral contact plug GPP filling or at least partially filling the second peripheral contact hole GPH may be formed. The first peripheral contact plug CPPb may be apart from an inter-gate insulating layer 172 and a gate cover insulating layer 174 with the contact spacer SPa therebetween. The contact spacer SPa may surround or at least partially surround an outer surface of the first peripheral contact plug CPPb.

Referring to FIG. 24, a semiconductor device 2a may be formed with reference to that illustrated in FIGS. 13A to 15E. Cross-sectional views of the semiconductor device 2a corresponding to lines A-A′, B-B′, C-C′, and D-D′ in FIG. 2 are substantially the same as those shown in FIGS. 15A to 15D.

In the semiconductor device 2a according to some embodiments, because the contact spacer SPa covers or at least partially covers the inner surface of the first peripheral contact hole CPHa, the first peripheral contact plug CPPb filling or at least partially filling the first peripheral contact hole CPHa may have substantially the same horizontal width and extend in the vertical direction (Z direction). Accordingly, the occurrence of a void in the first peripheral contact plug CPPb may be prevented, thereby securing connection reliability between components of the semiconductor device 2a.

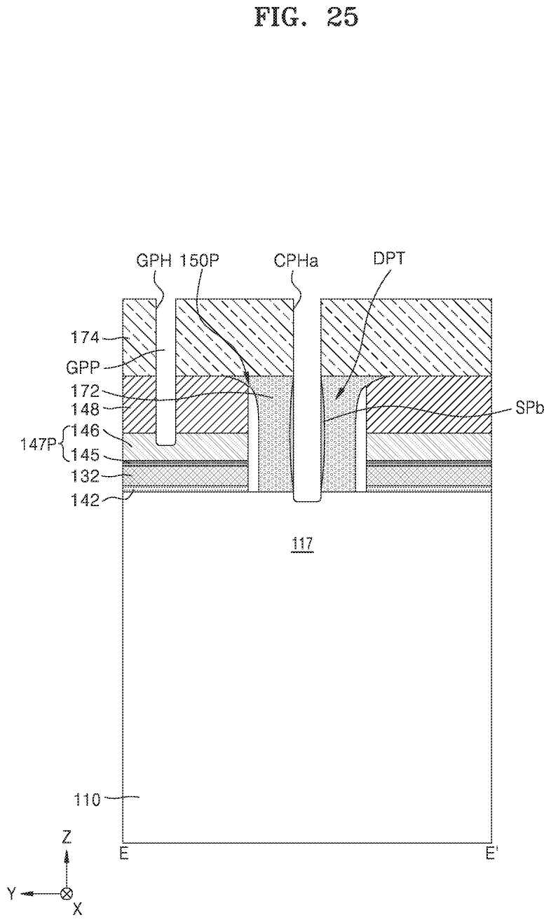

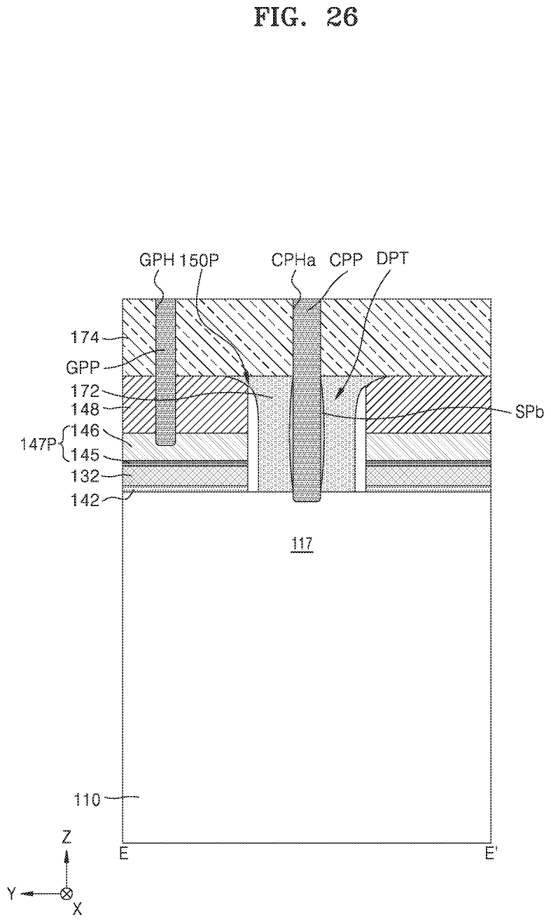

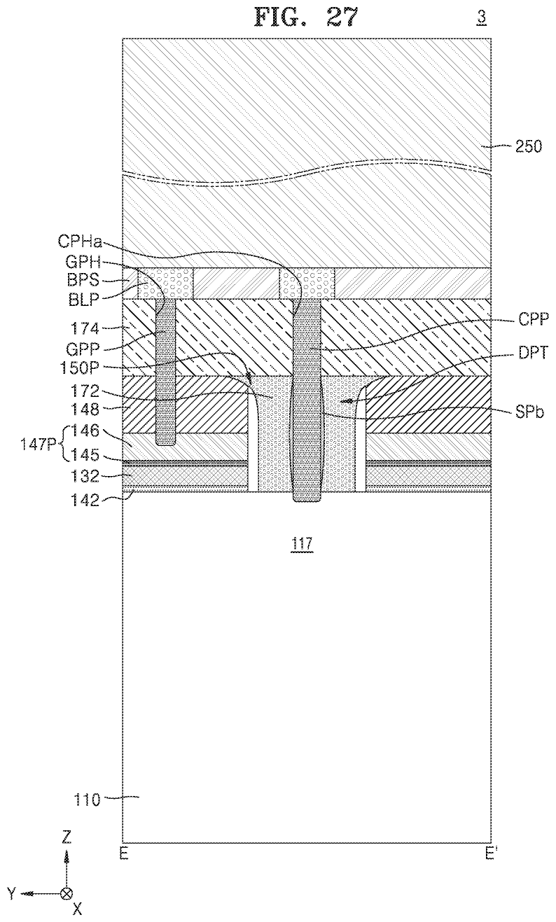

FIGS. 25 and 26 are cross-sectional views illustrating a method of manufacturing a semiconductor device, according to embodiments. FIG. 27 is a cross-sectional view illustrating a semiconductor device according to embodiments. Specifically, FIGS. 25 to 27 are cross-sectional views taken along lines E-E′ in FIG. 2.

Referring to FIG. 25, after forming a first peripheral contact hole CPHa and a second peripheral contact hole GPH as described with reference to FIG. 16, a contact spacer SPb covering a portion of the inner surface of the first peripheral contact hole CPHa may be formed. The contact spacer SPb may be formed to cover at least a portion of the inner surface of a portion of the first peripheral contact hole CPHa, which passes through the inter-gate insulating layer 172, in the first peripheral contact hole CPHa. For example, the contact spacer SPb may be formed to fill or at least partially fill a space of which the horizontal width is relatively widened due to bowing occurring at a portion of the first peripheral contact hole CPHa, which passes through the inter-gate insulating layer 172, in the first peripheral contact hole CPHa. The horizontal width of a space defined by the contact spacer SPb may have substantially the same horizontal width and extend in the vertical direction (Z direction). For example, the contact spacer SPb may include nitride.

Referring to FIG. 26, a first peripheral contact plug CPP filling or at least partially filling the first peripheral contact hole CPHa, of which the inner surface is covered or at least partially covered by the contact spacer SPb, and a second peripheral contact plug GPP filling or at least partially filling the second peripheral contact hole GPH may be formed. The contact spacer SPb may be placed between the first peripheral contact plug CPP and the inter-gate insulating layer 172. The contact spacer SPb may surround or at least partially surround a portion of an outer surface of the first peripheral contact plug CPPb. In some embodiments, the contact spacer SPb may not be placed between the first peripheral contact plug CPP and the gate cover insulating layer 174.

Referring to FIG. 27, a semiconductor device 3 may be formed with reference to that illustrated in FIGS. 13A to 15E. Cross-sectional views of the semiconductor device 3 corresponding to lines A-A′, B-B′, C-C′, and D-D′ in FIG. 2 are substantially the same as those shown in FIGS. 15A to 15D.

In the semiconductor device 3 according to some embodiments, because the contact spacer SPb covers a portion of the inner surface of the first peripheral contact hole CPHa, the first peripheral contact plug CPP filling or at least partially filling the first peripheral contact hole CPHa may have substantially the same horizontal width and extend in the vertical direction (Z direction). Accordingly, the occurrence of a void in the first peripheral contact plug CPP may be prevented, thereby securing connection reliability between components of the semiconductor device 3.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A method of manufacturing a semiconductor device, the method comprising:
preparing a substrate comprising a plurality of active regions and a peripheral active region defined by an isolation layer;
forming a word line in a word line trench that crosses the plurality of active regions;
forming a plurality of bit line structures, each of the plurality of bit line structures comprising a bit line on the plurality of active regions,
forming a plurality of gate line structures, each of the plurality of gate line structures comprising a gate line on the peripheral active region;
forming a plurality of buried contacts between the plurality of bit line structures, the plurality of buried contacts being connected to the plurality of active regions;
forming an inter-gate insulating layer between the plurality of gate line structures, the inter-gate insulating layer comprising an oxide having impurities;
forming a gate cover insulating layer at least partially covering the plurality of gate line structures and the inter-gate insulating layer;
forming a peripheral contact plug connected to the peripheral active region through the gate cover insulating layer and the inter-gate insulating layer;
forming a plurality of landing pads on the plurality of buried contacts;
forming a peripheral bit line on the peripheral contact plug; and
forming a plurality of capacitor structures on the plurality of landing pads.

2. The method of claim 1, wherein the forming of the inter-gate insulating layer comprises positioning top surfaces of the plurality of gate line structures and a top surface of the inter-gate insulating layer at a same vertical level such that the top surfaces of the plurality of gate line structures and the top surface of the inter-gate insulating layer are coplanar.

3. The method of claim 2, wherein the forming of the inter-gate insulating layer further comprises:
forming a preliminary inter-gate insulating layer at least partially filling spaces between the plurality of gate line structures and at least partially covering top surfaces of the plurality of gate line structures, the preliminary inter-gate insulating layer comprising an oxide having the impurities; and
removing an upper portion of the preliminary inter-gate insulating layer such that the plurality of gate line structures are exposed.

4. The method of claim 1, wherein the impurities comprise nitrogen, phosphorus, or carbon.

5. The method of claim 4, wherein the impurities comprise nitrogen, and
wherein an atomic ratio of nitrogen among nitrogen and oxygen in the inter-gate insulating layer is about 10% to about 30%.

6. The method of claim 4, wherein the impurities comprise phosphorus or carbon,
wherein, when the impurities comprise phosphorous, an atomic ratio of phosphorus among phosphorus and oxygen in the inter-gate insulating layer about 1% to about 5%, and
wherein, when the impurities comprise carbon, an atomic ratio of carbon among carbon and oxygen in the inter-gate insulating layer is about 1% to about 5%.

7. The method of claim 1, wherein the peripheral contact plug has a substantially constant horizontal width and extends in a vertical direction.

8. The method of claim 1, further comprising, prior to forming the peripheral contact plug, forming a contact spacer,
wherein the contact spacer surrounds at least a portion of an outer surface of the peripheral contact plug.

9. The method of claim 1, wherein a portion of the peripheral contact plug passing through the inter-gate insulating layer has an entasis shape, and
wherein a maximum horizontal width of the peripheral contact plug is greater than about 100% and less than about 110% of a minimum horizontal width of the peripheral contact plug.

10. The method of claim 1, further comprising, prior to forming the peripheral contact plug, forming a contact spacer,
wherein a portion of a space defined by peripheral contact hole that passes through the inter-gate insulating layer has an entasis shape,
wherein the contact spacer surrounds at least a portion of an outer surface of the peripheral contact plug that passes through the inter-gate insulating layer, and
wherein the peripheral contact plug has a substantially constant horizontal width and extends in a vertical direction.

11. A method of manufacturing a semiconductor device, the method comprising:
forming, on a substrate, a plurality of gate line structures, each of the plurality of gate line structures comprising a gate line;
forming a preliminary inter-gate insulating layer at least partially filling spaces between the plurality of gate line structures and at least partially covering top surfaces of the plurality of gate line structures, the preliminary inter-gate insulating layer comprising an oxide having first impurities;
forming an inter-gate insulating layer comprising an oxide having second impurities by removing an upper portion of the preliminary inter-gate insulating layer such that the plurality of gate line structures are exposed;
forming a gate cover insulating layer at least partially covering the plurality of gate line structures and the inter-gate insulating layer;
forming a peripheral contact hole through the gate cover insulating layer and the inter-gate insulating layer, the substrate being exposed at a bottom of the peripheral contact hole; and
forming a peripheral contact plug at least partially filling the peripheral contact hole.

12. The method of claim 11, wherein the first impurities of the oxide of the preliminary inter-gate insulating layer comprise nitrogen and oxygen, and
wherein an atomic ratio of nitrogen among the nitrogen and the oxygen in the oxide of the preliminary inter-gate insulating layer is about 10% to about 30%.

13. The method of claim 11, wherein, in the forming of the peripheral contact plug, the peripheral contact plug comprises a predetermined horizontal width and extends in a vertical direction.

14. The method of claim 13, wherein, in the forming of the peripheral contact hole, the peripheral contact hole comprises a predetermined horizontal width and extends in a vertical direction.

15. The method of claim 13, wherein, in the forming of the peripheral contact hole, a portion of a space defined by the peripheral contact hole and that passes through the inter-gate insulating layer has an entasis shape.

16. The method of claim 15, further comprising, prior to forming the peripheral contact plug, forming a contact spacer,
wherein the contact spacer surrounds at least a portion of an outer surface of the peripheral contact plug.

17. The method of claim 11, wherein the forming of the inter-gate insulating layer comprises removing an upper portion of the preliminary inter-gate insulating layer such that top surfaces of the plurality of gate line structures and a top surface of the inter-gate insulating layer are at a same vertical level and are coplanar.

18. A method of manufacturing a semiconductor device, the method comprising:
preparing a substrate in which a plurality of active regions and a peripheral active region are defined by an isolation layer;
forming a word line trench by removing portions of the isolation layer and portions of each of the plurality of active regions, the word line trench crossing the plurality of active regions in the substrate and extending in a first horizontal direction;
forming a word line in the word line trench;
forming a plurality of bit line structures extending parallel to each other in a second horizontal direction orthogonal to the first horizontal direction on the plurality of active regions;
forming a plurality of gate line structures, each of the plurality of gate line structures comprising a gate line on the peripheral active region;
forming a plurality of buried contacts between the plurality of bit line structures, the plurality of buried contacts being connected to the plurality of active regions;
forming a preliminary inter-gate insulating layer at least partially filling spaces between the plurality of gate line structures and at least partially covering top surfaces of the plurality of gate line structures, the preliminary inter-gate insulating layer comprising an oxide having first impurities comprising nitrogen;
forming an inter-gate insulating layer by removing an upper portion of the preliminary inter-gate insulating layer such that the plurality of gate line structures are exposed, the inter-gate insulating layer comprising an oxide having second impurities comprising nitrogen;
forming a gate cover insulating layer at least partially covering the plurality of gate line structures and the inter-gate insulating layer;
forming a first peripheral contact hole through the gate cover insulating layer and the inter-gate insulating layer, the peripheral active region being exposed at a bottom of the first peripheral contact hole;
forming a second peripheral contact hole through the gate cover insulating layer, wherein at least one gate line of the plurality of gate line structures is exposed at a bottom of the second peripheral contact hole;
forming a preliminary contact material layer at least partially filling the first peripheral contact hole and the second peripheral contact hole and at least partially covering a top surface of the gate cover insulating layer;
forming a first peripheral contact plug and a second peripheral contact plug at least partially filling the first peripheral contact hole and the second peripheral contact hole, respectively, by removing an upper portion of the preliminary contact material layer;
forming a plurality of landing pads on the plurality of buried contacts;
forming a peripheral bit line on each of the first peripheral contact plug and the second peripheral contact plug; and
forming a plurality of capacitor structures on the plurality of landing pads, wherein the first peripheral contact plug has a substantially constant horizontal width and extends in a vertical direction.

19. The method of claim 18, further comprising, prior to forming the preliminary contact material layer, forming a contact spacer covering at least a portion of an inner surface of the first peripheral contact hole,
wherein, in the forming of the first peripheral contact plug and the second peripheral contact plug, the contact spacer surrounds at least a portion of an outer surface of the first peripheral contact plug.

20. The method of claim 18, wherein the forming of the inter-gate insulating layer comprises positioning top surfaces of the plurality of gate line structures and a top surface of the inter-gate insulating layer at a same vertical level, such that the top surfaces of the plurality of gate line structures and the top surface of the inter-gate insulating layer are coplanar, and
wherein a top surface of each of the plurality of landing pads and a top surface of the peripheral bit line are positioned at a same vertical level.
